(19) United States
(12) Patent Application Publication
(10) Pub. No.: US 2025/0048902 A1
(43) Pub. Date: Feb. 6, 2025

(54) ORGANIC LIGHT EMITTING DISPLAY APPARATUS INCLUDING LIGHT GUIDING PART AND METHOD OF MANUFACTURING THE LIGHT GUIDING PART

(71) Applicant: LG Display Co., Ltd., Seoul (KR)

(72) Inventors: SunWoong KIM, Paju-si (KR); JuHun MIN, Paju-si (KR); SeungSoo YANG, Paju-si (KR); DongUk KIM, Paju-si (KR)

(73) Assignee: LG Display Co., Ltd., Seoul (KR)

(21) Appl. No.: 18/790,942

(22) Filed: Jul. 31, 2024

(30) Foreign Application Priority Data
Jul. 31, 2023 (KR) 10-2023-0100107
Jul. 23, 2024 (KR) 10-2024-0097386

(51) Int. Cl. H10K 59/80; H10K 59/12

(52) U.S. Cl. CPC H10K 59/8791; H10K 59/1201

(57) ABSTRACT

Disclosed is an organic light emitting display apparatus comprising a display panel including a circuit element layer and a light guide part disposed on the circuit element layer, the light guide part having a bottom surface and a top surface opposite to the bottom surface. The light guide part includes a plurality of lens patterns extending from the bottom surface toward the top surface and disposed irregularly in the light guide part, a lens connection part disposed between the plurality of lens patterns and in contact with the plurality of lens patterns, and a filling layer disposed on the plurality of lens patterns and the lens connection part.

### CROSS-REFERENCE TO RELATED APPLICATIONS

This application claims priority to the Korean Patent Application No. 10-2023-0100107 filed on Jul. 31, 2023 in the Republic of Korea, and the Korean Patent Application No. 10-2024-0097386 filed on Jul. 23, 2024 in the Republic of Korea, the entire contents of all these applications being expressly incorporated by reference as if fully set forth herein into the present application.

### BACKGROUND

### Technical Field

The present disclosure relates to an organic light emitting display apparatus including a light guide part capable of reducing reflectance by external light and a method of manufacturing the light guide part.

### Discussion of the Related Art

As the information society develops, demands for display apparatus are also developing in various forms. In response, various flat panel display apparatus such as a liquid crystal display (LCD), an organic light emitting display (OLED), and a micro LED display have been developed in recent years.

Organic light-emitting displays are attracting attention as next-generation flat-panel displays because they have a high response speed, low power consumption, and self-luminous light that does not require a separate light source unlike liquid crystal displays.

The organic light emitting display apparatus displays an image through light emission of a light emitting element including a light emitting layer interposed between two electrodes.

Meanwhile, when light is introduced into the display apparatus from the outside, the introduced light is reflected by electrodes and wirings provided inside the display apparatus to form reflected light. In this case, when the reflected light is emitted through the light emission surface of the display apparatus, the reflected light can be visually recognized as a mura pattern, for example, a rainbow mura pattern or a ring mura pattern. In this case, there is a problem that it is difficult to implement Real Black in the turn-off state of the display apparatus.

To solve this problem, a light guide part including a plurality of lens patterns is introduced into a display apparatus. However, the heights of the plurality of lens patterns differ from each other, resulting in a contrast difference, in which Sparkle is recognized, which tires the user's eyes and makes it difficult to implement Real Black.

### SUMMARY OF THE DISCLOSURE

The present disclosure has been made in view of the above problems, and it is an object of the present disclosure to provide an organic light emitting display apparatus with an improved sparkle includes a plurality of lens patterns that can minimize or reduce the occurrence of Rainbow Mura and Ring Mura phenomena due to the reflection of external light and has a lens connection part between the plurality of lens patterns to reduce the contrast deviation by reducing the height differences between the plurality of lens patterns and a plurality of concave portions disposed between the plurality of lens patterns.

In accordance with an aspect of the present disclosure, the above and other objects can be accomplished by the provision of an organic light emitting display apparatus comprising a display panel including a circuit element layer and a light guide part disposed on the circuit element layer, the light guide part having a bottom surface and a top surface opposite to the bottom surface, wherein the light guide part includes a plurality of lens patterns extending from the bottom surface toward the top surface and disposed irregularly in the light guide part, a lens connection part disposed between the plurality of lens patterns and in contact with the plurality of lens patterns, and a filling layer disposed on the plurality of lens patterns and the lens connection part.

Furthermore, the above and other objects can be accomplished by the provision of a method of manufacturing a light guiding part of an organic light emitting display apparatus comprising forming a first pattern using a laser in a surface of a mold, the first pattern comprising a plurality of first concave portions, forming a second pattern on the surface of the mold by forming a plurality of second concave portions at a boundary between the plurality of first concave portions of the first patterns through a blasting process, forming a plurality of lens patterns and a lens connection part between a plurality of lens patterns using the mold including the first pattern and the second pattern, and forming a filling layer on the plurality of lens patterns and the lens connection part, wherein the plurality of first concave portions correspond to the plurality of lens patterns, and the plurality of second concave portions correspond to the lens connection part.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a plan view of an organic light emitting display apparatus according to an embodiment of the present disclosure.

FIG. 2 is a schematic partial cross-sectional view of an organic light emitting display apparatus according to an embodiment of the present disclosure. In this case, FIG. 2 corresponds to a cross-section taken along line I-I′ illustrated in FIG. 1.

FIG. 3A is a plan view of a light guide part according to an embodiment of the present disclosure, and FIG. 3B is a plan view illustrating only a plurality of lens patterns except for a lens connection part of the light guide part according to an embodiment of the present disclosure.

FIG. 4A is a partial cross-sectional view illustrating a portion of the light guide part according to an embodiment of the present disclosure. In this case, FIG. 4A is a cross-sectional view taken along line II-II′ illustrated in FIG. 3A.

FIG. 4B is a partial cross-sectional view illustrating a portion of the light guide part according to an embodiment of the present disclosure. In this case, FIG. 4B is a cross-sectional view taken along line III-III′ illustrated in FIG. 3A.

FIG. 4C is a partial cross-sectional view illustrating a portion of the light guide part according to an embodiment of the present disclosure. In this case, FIG. 4C is a cross-sectional view taken along line IV-IV′ illustrated in FIG. 3A.

FIG. 5 is a diagram for explaining that a sparkle occurs when a lens connection part is not present in the light guide part according to an embodiment of the present disclosure.

FIGS. 6A to 6D are cross-sectional views schematically illustrating a method of manufacturing a light guide part according to an embodiment of the present disclosure.

FIGS. 7A and 7B are schematic views of a surface of a mold for forming a light guide part according to an embodiment of the present disclosure, and in this case, FIG. 7A relates to the surface of the mold shown in FIG. 6A, and FIG. 7B relates to the surface of the mold shown in FIG. 6B.

FIGS. 8A to 8D are partial cross-sectional views schematically illustrating a method of manufacturing a light guide part according to an embodiment of the present disclosure. In this case, FIGS. 8A and 8B are partial cross-sections taken along line V-V′ illustrated in FIGS. 7A and 7B, respectively, and FIGS. 8C and 8D are partial cross-sections taken along line II-II′ illustrated in FIG. 3A.

FIGS. 9A to 9D are partial cross-sectional views schematically illustrating a method of manufacturing the light guide part according to an embodiment of the present disclosure. In this case, FIGS. 9A and 9B are partial cross-sections taken along line VI-VI′ illustrated in FIGS. 7A and 7B, respectively, and FIGS. 9C and 9D are partial cross-sections taken along line III-III′ illustrated in FIG. 3A.

FIGS. 10A to 10D are partial cross-sectional views schematically illustrating a method of manufacturing a light guide part according to an embodiment of the present disclosure. In this case, FIGS. 10A and 10B are partial cross-sections taken along line VII-VII′ illustrated in FIGS. 7A and 7B, respectively, and FIGS. 10C and 10D are partial cross-sections taken along line IV-IV′ illustrated in FIG. 3A.

FIG. 11 is a cross-sectional view of a light guide member according to another embodiment of the present disclosure.

FIGS. 12A to 12C are cross-sectional views schematically illustrating a process of manufacturing a light guide member according to another embodiment of the present disclosure.

FIGS. 13A to 13C are examples of planar TEM photographs of a light guide member according to another embodiment of the present disclosure.

FIGS. 14A and 14B are examples of planar TEM photographs of a light guide member according to another embodiment of the present disclosure.

FIG. 15 is a cross-sectional view of a light guide member according to another embodiment of the present disclosure.

FIGS. 16A to 16C are cross-sectional views schematically illustrating a process of manufacturing a light guide member according to another embodiment of the present disclosure.

FIGS. 17A to 17C are examples of planar TEM photographs of a light guide member according to another embodiment of the present disclosure.

### DETAILED DESCRIPTION OF THE EMBODIMENTS

Advantages and features of the present disclosure, and implementation methods thereof will be clarified through the following embodiments, described with reference to the accompanying drawings. The present disclosure can, however, be embodied in different forms and should not be construed as being limited to the embodiments set forth herein. Rather, these embodiments are provided so that this disclosure will be thorough and complete, and will fully convey the scope of the present disclosure to those skilled in the art. Further, the present disclosure is only defined by the scope of the claims.

The shapes, sizes, ratios, angles, and numbers disclosed in the drawings for describing embodiments of the present disclosure are merely examples, and thus the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted.

In the case in which “comprise,” “have,” and “include” described in the present disclosure are used, another part can also be present unless “only” is used. The terms in a singular form can include plural forms unless noted to the contrary.

In construing an element, the element is construed as including an error region although there is no explicit description thereof.

In describing a positional relationship, for example, when the positional order is described as “on,” “above,” “below,” “beneath”, and “next,” the case of no contact therebetween can be included, unless “just” or “direct” is used.

If it is mentioned that a first element is positioned “on” a second element, it does not mean that the first element is essentially positioned above the second element in the figure. The upper part and the lower part of an object concerned can be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, when the temporal order is described as “after,” “subsequent,” “next,” and “before,” a case which is not continuous can be included, unless “just” or “direct” is used.

It will be understood that, although the terms “first,” “second,” etc. can be used herein to describe various elements, these elements should not be limited by these terms. These terms are only used to distinguish one element from another. For example, a first element could be termed a second element, and, similarly, a second element could be termed a first element.

It should be understood that the term “at least one” includes all combinations related with any one item. For example, “at least one among a first element, a second element and a third element” can include all combinations of two or more elements selected from the first, second and third elements as well as each element of the first, second and third elements.

Features of various embodiments of the present disclosure can be partially or overall coupled to or combined with each other, and can be variously inter-operated with each other and driven technically The embodiments of the present disclosure can be carried out independently from each other, or can be carried out together in a co-dependent relationship. Further, the term “can” encompasses all the meanings and coverages of the term “may”. In addition, all the components of each display apparatus according to all embodiments of the present disclosure are operatively coupled and configured.

In the drawings, the same or similar elements are denoted by the same reference numerals even though they are depicted in different drawings.

In the embodiments of the present disclosure, a source electrode and a drain electrode are distinguished from each other, for convenience of explanation. However, the source electrode and the drain electrode are used interchangeably. Thus, the source electrode can be the drain electrode, and the drain electrode can be the source electrode. Further, the source electrode in any one embodiment of the present disclosure can be the drain electrode in another embodiment of the present disclosure, and the drain electrode in any one embodiment of the present disclosure can be the source electrode in another embodiment of the present disclosure.

In one or more embodiments of the present disclosure, for convenience of explanation, a source region is distinguished from a source electrode, and a drain region is distinguished from a drain electrode. However, embodiments of the present disclosure are not limited to this structure. For example, a source region can be a source electrode, and a drain region can be a drain electrode. Further, a source region can be a drain electrode, and a drain region can be a source electrode.

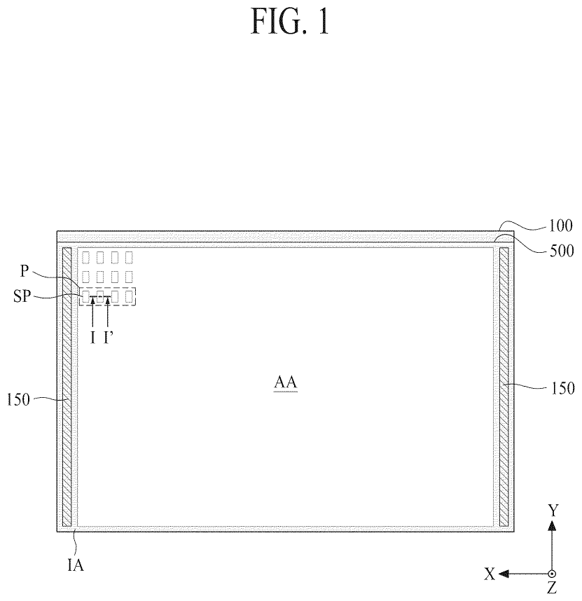

FIG. 1 is a plan view of an organic light emitting display apparatus according to an embodiment of the present disclosure.

As shown in FIG. 1, the organic light emitting display apparatus according to an embodiment of the present disclosure can include a display panel including a first substrate 100 and a second substrate 500 opposite to the first substrate 100, which are bonded to each other.

The first substrate 100 can include a thin film transistor and can be a transparent glass substrate or a plastic substrate. The first substrate 100 can include a display area (or active area) AA in which an image is displayed and a non-display area (or inactive area) IA in which an image is not displayed according to whether an image is displayed by a pixel.

The display area AA can be an area in which an image is displayed, and can be a pixel array area, an active area, a pixel array unit, a display unit, or a screen. The display area AA can include a plurality of pixels P.

The plurality of pixels P can be disposed along each of a first direction (e.g., X direction) and a second direction (e.g., Y direction) crossing the first direction X. Each of the plurality of pixels P can be a unit region in which actual light is emitted. For example, the plurality of pixels P can be disposed to have a pixel pitch along the first direction X. The pixel pitch can be a size of each of the plurality of pixels P with respect to the first direction X, a distance between one side of each of two pixels P adjacent along the first direction X, or a distance between central portions of two pixels P adjacent along the first direction X.

Each of the plurality of pixels P can include a plurality of adjacent sub-pixels SP. For example, the plurality of sub-pixels SP can constitute the plurality of pixels P. For example, the first direction X can be a first length direction, a long side length direction, a horizontal direction, or a first horizontal direction of the first substrate 100. For example, the second direction Y can be a second length direction, a short side length direction, a vertical direction, or a second horizontal direction of the first substrate 100.

The non-display area IA is an area in which no image is displayed, and can be a peripheral circuit area, a signal supply area, an inactive area, or a bezel area. The non-display area IA can be configured to surround the display area AA. The display panel or the first substrate 100 can further include a peripheral circuit unit 150 disposed in the non-display area IA. The peripheral circuit unit 150 can include a gate driving circuit connected to the plurality of sub-pixels SP.

The second substrate 500 can be configured to overlap the display area AA. The second substrate 500 can be bonded to face the first substrate 100 through an adhesive member (or a transparent adhesive or optically clear adhesive), or can be disposed in a manner in which an organic material or an inorganic material is stacked on the first substrate 100. The second substrate 500 can be an upper substrate or an encapsulation substrate, and can be used for encapsulating the first substrate 100.

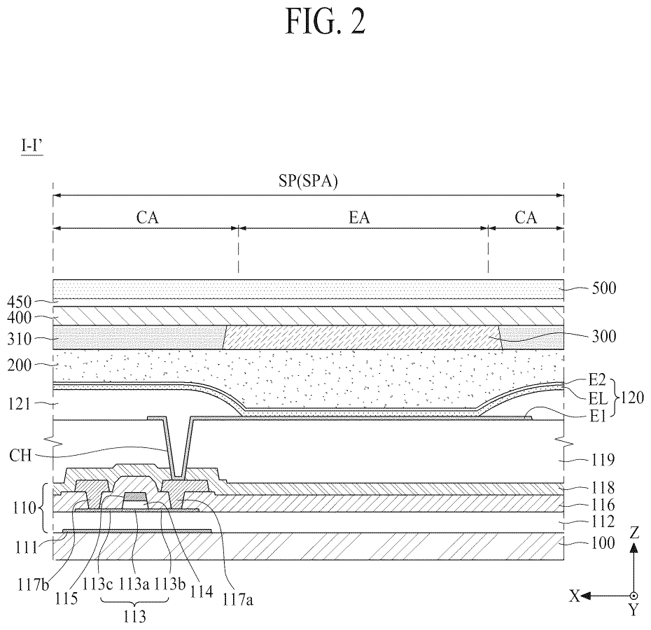

FIG. 2 is a schematic partial cross-sectional view of an organic light emitting display apparatus according to an embodiment of the present disclosure. In this case, FIG. 2 corresponds to a cross-section taken along line I-I′ illustrated in FIG. 1.

As shown in FIG. 2, the organic light emitting display apparatus according to an embodiment of the present disclosure can include a first substrate 100, a circuit element layer 110, a light emitting element layer 120, an encapsulation layer 200, a color filter 300, a light guide part 400, and a second substrate 500.

The first substrate 100 can include a thin film transistor, and can be a first substrate, a base substrate, a lower substrate, a transparent glass substrate, a transparent plastic substrate, or a base member.

The first substrate 100 can include a circuit element layer 110, a planarization layer 119, and a light emitting element layer 120. The circuit element layer 110 can include a buffer layer 112, a pixel circuit, and a protective layer 118.

The buffer layer 112 can be disposed on the entire first surface (or front surface) of the first substrate 100. The buffer layer 112 can serve to block diffusion of a material contained in the first substrate 100 into the pixel circuit during a high-temperature process during a thin film transistor manufacturing process or can also serve to prevent external moisture or humidity from penetrating toward the light emitting element layer 120. Optionally, the buffer layer 112 can be omitted in some cases.

The pixel circuit can include a driving thin film transistor disposed in the circuit area CA of each subpixel SP. The driving thin film transistor can include an active layer 113, a gate insulating layer 114, a gate electrode 115, an interlayer insulating layer 116, a source electrode 117a, and a drain electrode 117b.

The active layer 113 can be formed of a semiconductor material based on any one of amorphous silicon, polycrystalline silicon, oxide, and organic material. The active layer 113 can include a channel region 113a, a drain region 113c, and a source region 113b.

The gate insulating layer 114 can be formed in an island shape only on the channel region 113a of the active layer 113 or can be formed on the entire front surface of the first substrate 100 or the buffer layer 112 on which the active layer 113 is disposed.

The gate electrode 115 can be disposed on the gate insulating layer 114 to overlap the channel region 113a of the active layer 113.

The interlayer insulating layer 116 can be formed on the gate electrode 115 and the drain region 113c and the source region 113b of the active layer 113. The interlayer insulating layer 116 can be formed on the entire front surface of the first substrate 100 or the buffer layer 112. For example, the interlayer insulating layer 116 can be formed of an inorganic material or an organic material.

The source electrode 117a can be disposed on the interlayer insulating layer 116 to be electrically connected to the source region 113b of the active layer 113. The drain electrode 117b can be disposed on the interlayer insulating layer 116 to be electrically connected to the drain region 113c of the active layer 113.

The pixel circuit can further include at least one capacitor and at least one switching thin film transistor disposed in the circuit area CA together with the driving thin film transistor.

The organic light emitting display apparatus according to the present disclosure can further include a light blocking layer 111 provided under the active layer 113 of the driving thin film transistor, and/or an active layer of the switching thin film transistor. The light blocking layer 111 can be configured to minimize or prevent a change in a threshold voltage of the thin film transistor due to external light.

The protective layer 118 can be configured on the pixel circuit. For example, the protective layer 118 can be configured to cover the source electrode 117a, the drain electrode 117b of the driving thin film transistor, and the interlayer insulating layer 116. For example, the protective layer 118 can be formed of an inorganic insulating material, and can be expressed in terms of a passivation layer or the like.

The planarization layer 119 can be provided on the circuit element layer 110. The planarization layer 119 can be formed on the entire display area and the rest of the non-display area except for a pad area. For example, the planarization layer 119 can include an extension part (or an expansion part) extending or expanding from the display area toward the non-display area except for the pad area. Thus, the planarization layer 119 can have a size relatively larger than that of the display area.

The planarization layer 119 according to an embodiment can be formed to have a relatively large thickness to provide a planarization surface on the circuit element layer 110. For example, the planarization layer 119 can be made of an organic material such as photoacrylic, benzocyclobutene, polyimide, fluorine resin, etc.

Meanwhile, although not shown in detail, the planarization layer 119 can include a light extraction unit disposed in each sub-pixel SP. The light extraction unit can be formed in the planarization layer 119 to overlap a light emitting area EA defined in the sub-pixel area SPA of each sub-pixel SP. In this case, the light extraction unit can be formed in the planarization layer 119 to have a curved portion (or a non-flat portion). In this case, the curved portion can include a plurality of concave portions and a plurality of convex portions. The light extraction unit can be formed in the planarization layer 119 to have a curved (or uneven) shape. When the light extraction unit is provided in the planarization layer 119, external extraction efficiency of light emitted from the light emitting element layer 120 can increase.

The light emitting element layer 120 can overlap the light emitting area EA of each subpixel SP. The light emitting element layer 120 according to an embodiment can include a first electrode E1, a light emitting layer EL, and a second electrode E2. For example, the first electrode E1, the light emitting layer EL, and the second electrode E2 can be configured to emit light toward the second substrate 500 according to a top emission method. However, the present disclosure is not limited thereto, and the first electrode E1, the light emitting layer EL, and the second electrode E2 can be configured to emit light toward the first substrate 100 according to a bottom emission method.

The first electrode E1 can be formed on the planarization layer 119 in the sub-pixel area SPA to be electrically connected to the source electrode 117a of the driving thin film transistor. One end of the first electrode E1 adjacent to the circuit area CA can be electrically connected to the source electrode 117a of the driving thin film transistor through an electrode contact hole CH provided in the planarization layer 119 and the protective layer 118.

The light emitting layer EL can be formed on the first electrode E1 to be in direct contact with the first electrode E1.

The light emitting layer EL according to an embodiment can include two or more organic emission layers for emitting white light. For example, the light emitting layer EL can include a first organic emission layer emitting first light and a second organic emission layer emitting second light for emitting white light by mixing the first light and the second light.

The second electrode E2 can be formed on the light emitting layer EL to be in direct contact with the light emitting layer EL. The second electrode E2 can be formed (or deposited) on the light emitting layer EL to have a relatively thin thickness compared to the light emitting layer EL. The second electrode E2 can be a cathode electrode.

The first electrode E1 according to an embodiment of the present disclosure can include a metal material having high reflectivity in order to reflect light emitted from the light emitting layer EL and incident thereto toward the second substrate 500. For example, the first electrode E1 can include a single-layered structure or a multilayer structure formed of any one material selected from aluminum (Al), silver (Ag), molybdenum (Mo), gold (Au), magnesium (Mg), calcium (Ca), or barium (Ba). The first electrode E1 can be an anode electrode.

Meanwhile, although not shown in detail in the drawing, when the light extraction unit is provided in the planarization layer 119, the first electrode E1, the light emitting layer EL, and the second electrode E2 can have a surface shape that directly follows a surface morphology of the light extraction unit including a plurality of convex portions and a plurality of concave portions. For example, the first electrode E1, the light emitting layer EL, and the second electrode E2 are formed in a conformal shape that directly follows the surface shape (or morphology) of the light extraction unit by a deposition process, and thus can have a cross-sectional structure having the same shape as the light extraction unit.

The organic light emitting display apparatus according to the exemplary configuration of the present disclosure can further include a bank layer 121. The bank layer 121 can be disposed on the planarization layer 119 and the edge of the first electrode E1. The bank layer 121 can be formed of a transparent material or an opaque material. For example, the bank layer 121 can be a transparent bank layer or a black bank layer. For example, the bank layer 121 can be formed of a photosensitizer including a black pigment, and in this case, the bank layer 121 can also serve as a light blocking member between the adjacent sub-pixels SP.

The encapsulation layer 200 can be formed on the first substrate 100 to cover the light emitting element layer 120. The encapsulation layer 200 can be formed on the second electrode E2. For example, the encapsulation layer 200 can overlap the display area. The encapsulation layer 200 can protect the thin film transistor and the light emitting layer EL from external impact and can serve to prevent oxygen or/and moisture, further particles from penetrating into the light emitting layer EL.

The encapsulation layer 200 according to the present disclosure can include a plurality of inorganic encapsulation layers. In addition, the encapsulation layer 200 can further include at least one organic encapsulation layer interposed between the plurality of inorganic encapsulation layers. The encapsulation layer 200 according to another embodiment can be changed into a filler overlapping the entire display area, and in this case, the second substrate 500 can be bonded to the first substrate 100 through a filler. The filler can include a getter material that absorbs oxygen or/and moisture.

The color filter 300 can be provided on the encapsulation layer 200. Specifically, it can be disposed between the encapsulation layer 200 and the second substrate 500. The color filter 300 can be disposed between the encapsulation layer 200 and the second substrate 500 to overlap at least one light emitting area EA. For example, the color filter 300 can be formed directly on the upper surface of the encapsulation layer 200 to overlap the light emitting area EA. In this case, the color filter 300 can directly contact the upper surface of the encapsulation layer 200. However, the present disclosure is not limited thereto, and the color filter 300 can be disposed on the inner surface of the second substrate 500 facing the upper surface of the encapsulation layer 200 to overlap the light emitting area EA. For example, the second substrate 500 having the color filter 300 can be coupled to the encapsulation layer 200 via a transparent adhesive member.

The color filter 300 can have a width wider than that of the light emitting area EA. For example, the color filter 300 can have a width corresponding to the entire sub-pixel area SPA of each sub-pixel SP, thereby reducing light leakage between adjacent sub-pixels SP.

The color filter 300 according to the present disclosure can be configured to transmit a wavelength of a color set in the sub-pixel SP. For example, when one pixel P is composed of first to fourth sub-pixels, the color filter 300 can include a red color filter provided in the first sub-pixel emitting red light, a green color filter provided in the third sub-pixel emitting green light, and a blue color filter provided in the fourth sub-pixel emitting blue light. The second sub-pixel emitting white light can not include a color filter or can include a transparent material for step compensation, thereby emitting white light.

The black matrix 310 can be provided between a plurality of color filters 300.

The black matrix 310 can be disposed to overlap with the remaining regions of each sub-pixel SP except for the light emitting area EA. Alternatively, the remaining region of each sub-pixel SP except for the light emitting area EA can include a stacked structure of at least two color filters instead of the black matrix 310. For example, the remaining region of each sub-pixel SP except for the light emitting area EA can include a stacked structure of at least two of a red color filter, a green color filter, and a blue color filter. The stacked structure of at least two color filters can prevent color mixing between the adjacent sub-pixels SP instead of the black matrix 310.

The second substrate 500 can be provided on the color filter 300. The second substrate 500 can be made of a plastic material, a glass material, or a metal material. Meanwhile, when the encapsulation layer 200 includes a plurality of inorganic encapsulation layers, the second substrate 500 can be omitted.

Optionally, when the encapsulation layer 200 is changed to a filler, the second substrate 500 can be combined with a filler, and in this case, the second substrate 500 can be made of a plastic material, a glass material, or a metal material.

The light guide part 400 can be provided between the color filter 300 and the second substrate 500. The light guide part 400 can be disposed or configured on a first surface of the second substrate 500, i.e., a lower surface, opposite to a second surface, i.e., an upper surface (as a light emitting surface) of the second substrate 500.

The light guide part 400 according to an embodiment of the present disclosure can be coupled to the lower surface of the second substrate 500 via an adhesive member (or a first transparent adhesive member) 450. For example, the light guide part 400 can be coupled to the entire lower surface of the second substrate 500 via the adhesive member 450. In this case, the light guide part 400 can have the same size as the lower surface of the second substrate 500.

The light guide part 400 can be configured to improve black visibility characteristics due to reflection of external light in a non-driving or turn-off state of the organic light emitting display apparatus. For example, in a non-driving or turn-off state of the organic light emitting display apparatus, light incident from the outside is reflected by electrodes and wirings of the circuit element layer 110 to form reflected light, and the reflected light can form a rainbow mura pattern (or rainbow stain pattern) that has a rainbow color and spreads radially and/or a circular ring pattern in a radial form due to the dispersion characteristics of light according to diffraction characteristics.

The reflected light can cause multiple interferences and/or reinforcement interferences of light according to the difference in refractive angles for each wavelength to generate a rainbow mura pattern and/or a circular ring pattern in the form of radiation, thereby reducing black visibility characteristics.

The light guide part 400 according to an embodiment of the present disclosure can be configured to diffract and/or scatter external light incident into the display apparatus through the second substrate 500 from the outside based on the light refracting principle according to the cross-sectional shape having the refractive index difference, or to redisperse (or disperse) the diffraction dispersion spectrum of the reflected light. For example, the light guide part 400 can suppress or minimize the occurrence of the radial rainbow mura phenomenon through mixing between adjacent spectra according to the diffraction order of the reflected light by reducing the intensity of the diffraction dispersion spectrum or redispersing the diffraction dispersion spectrum to greatly expand the size of the spectrum.

The light guide part 400 can include a lens pattern. The lens pattern can diffract and/or scatter external light incident on the light emitting element layer 120 from the outside based on the light refraction principle having a difference in refractive index, or diffract and/or scatter the reflected light. Accordingly, the occurrence of a rainbow mura pattern and/or a circular ring pattern can be reduced or minimized by canceling or minimizing multiple interferences and/or reinforcing interferences of the reflected light, and according to an embodiment of the present disclosure, a decrease in black visibility characteristics caused by reflection of external light can be reduced, and real black can be realized in a non-driving or turn-off state of the display apparatus. For example, the light guide part 400 can be a light guide pattern unit, a light refracting unit, a light refracting member, a spectrum dispersion unit, a spectrum reduction unit, or a diffraction spectrum dispersion unit.

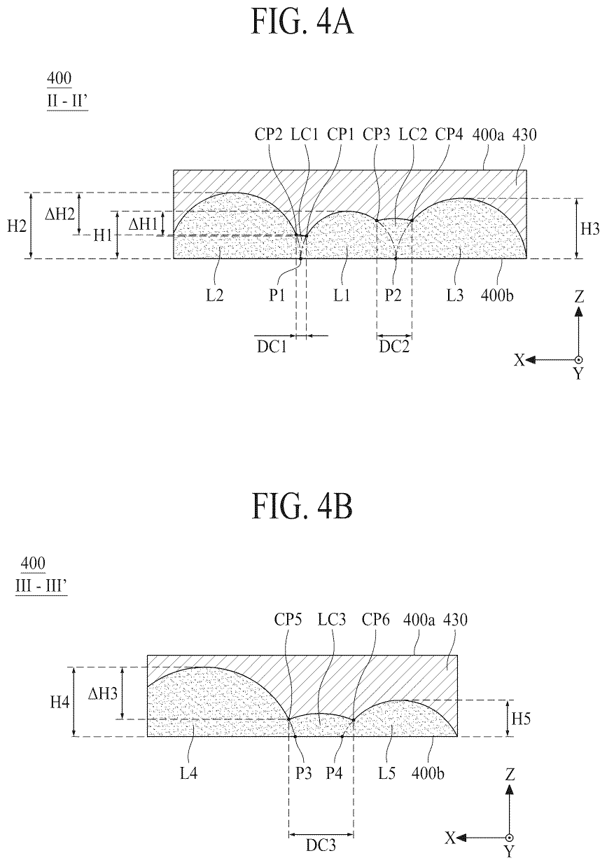

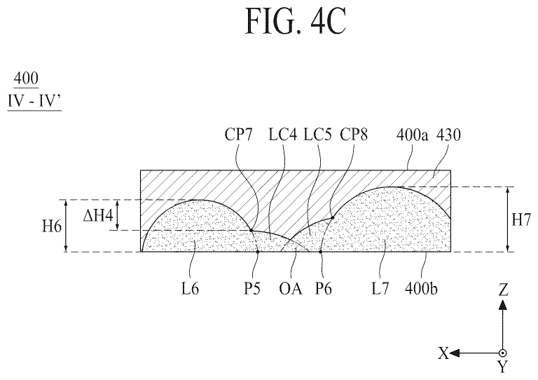

According to an embodiment of the present disclosure, the light guide part 400 can have a haze value equal to or greater than 5% and equal to or less than 15%. When the haze value of the light guide part 400 is less than 5%, the mura pattern due to reflection of external light can be recognized, and when the haze value of the light guide part 400 is greater than 15%, a sparkle can be recognized according to a height difference between a plurality of lens patterns (see L1 to Ln of FIG. 4A) and a plurality of concave portions (see CP1 to CPn of FIG. 4A) provided between the plurality of lens patterns. Meanwhile, it is preferable that the haze value of the light guide part 400 is greater than or equal to 7% and less than or equal to 13%.

In this case, the haze value can be defined as a surface characteristic of the sample, for example, an optical characteristic of the sample with respect to roughness, when the light is transmitted to the sample. Specifically, the haze value of the light guide part 400 according to an embodiment of the present disclosure can be phototopically measured according to ASTM D 1003-07, “a standard test method for haze and luminous transmittance of transparent plastics.”

Meanwhile, although not shown, the organic light emitting display apparatus according to an embodiment of the present disclosure can further include a polarizing member. The polarizing member can be provided on the light guide part 400 to block light introduced from the outside from being reflected by a pixel circuit or the like.

By including the light guide part 400, the organic light emitting display apparatus according to an embodiment of the present disclosure can improve black visibility characteristics due to reflection of external light, occurrence of Rainbow Mura and Ring Mura phenomena can be minimized or reduced, thereby realizing real black in a non-driving or turn-off state of the display apparatus.

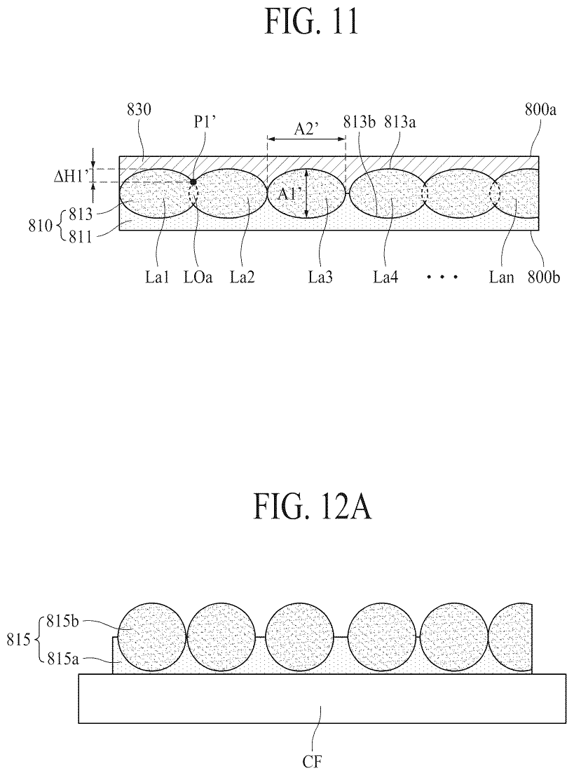

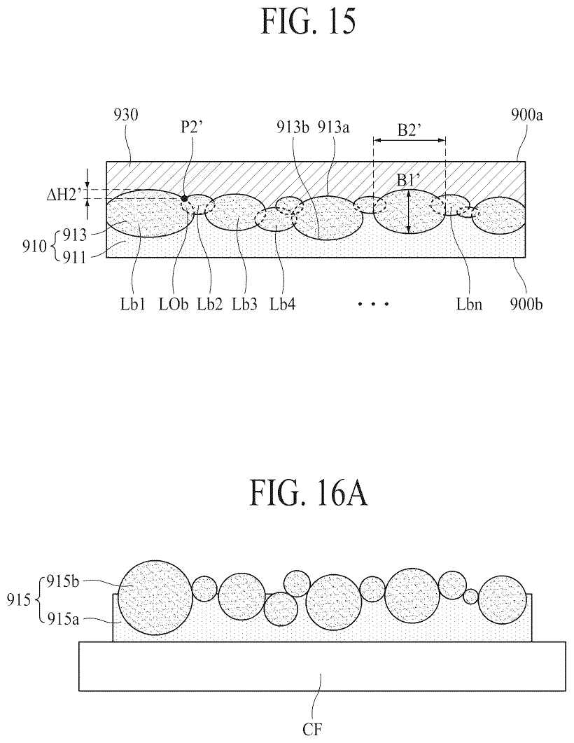

Furthermore, only the light guide part 400 according to an embodiment has been described in the embodiment of FIG. 2, but it is not limited thereto, and a light guide member 800 according to FIG. 11 or a light guide member 900 according to FIG. 15 can be applied as another embodiment. It will be understood that a light guide part may be referred as a light guide member herein.

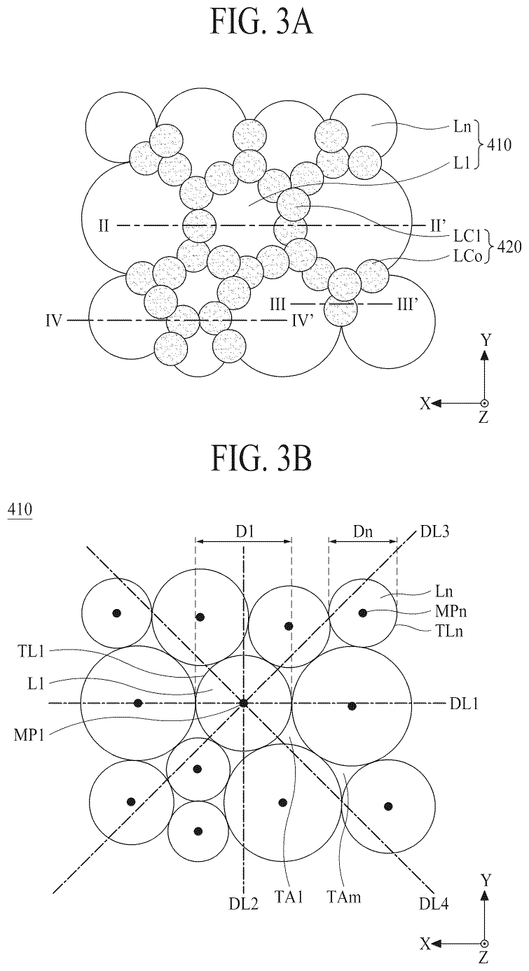

FIG. 3A is a plan view of the light guide part according to an embodiment of the present disclosure, and FIG. 3B is a plan view illustrating only a plurality of lens patterns except for a lens connection part of the light guide part according to an embodiment of the present disclosure.

As shown in FIG. 3A, the light guide part 400 according to an embodiment of the present disclosure can include a plurality of lens patterns 410 and a lens connection part 420. Meanwhile, although the lens connection part 420 is described in FIG. 3A as being provided only in some regions of the plurality of lens patterns 410 for convenience of explanation, the lens connection part 420 can be provided in all boundaries provided between the plurality of lens patterns 410.

According to an embodiment of the present disclosure, the plurality of lens patterns 410 and the lens connection part 420 can be irregularly disposed in an amorphous state in the light guide part 400. Meanwhile, a configuration in which the plurality of lens patterns 410 are irregularly disposed in an amorphous state will be described in detail with reference to FIG. 3B below.

As shown in FIG. 3B, the plurality of lens patterns 410 can include a first lens pattern L1 to a nth lens pattern Ln. In this case, each of the lens patterns L1 to Ln (in this case, n is an integer equal to or greater than 1) can be provided in a circular shape on a plane. However, the shape of each of the plurality of lens patterns is not limited thereto, and can be provided in various shapes according to a level of the art.

Each of the plurality of lens patterns L1 to Ln can include center points MP1 to MPn (in this case, n is an integer greater than or equal to 1) provided at each center thereof. According to an embodiment of the present disclosure, the center points MP1 to MPn of each of plurality of the lens patterns L1 to Ln can or can not be provided on the same line.

For example, in the first central point MP1 of the first lens pattern L1 among the plurality of lens patterns 410, a virtual first line DL1 extending in the first direction X through the first central point MP1, a virtual second line DL2 extending in the second direction Y through the first central point MP1, a virtual third line DL3 and a virtual fourth line DL4 provided between the virtual first line DL1 and the virtual second line DL2 through the first central point MP1 and orthogonal to each other can be provided.

The virtual first line DL1 to the virtual fourth line DL4 of the first lens pattern L1 can or can not overlap the central points MP2 to MPn of other adjacent lens patterns L2 to Ln.

Each of the plurality of lens patterns L1 to Ln can have a predetermined diameter D1 to Dn (in this case, n is an integer greater than or equal to 1). In this case, the plurality of lens patterns L1 to Ln can have different diameters D1 to Dn, or some of them can be the same.

According to an embodiment of the present disclosure, each of the diameters D1 to Dn of the plurality of lens patterns L1 to Ln can be equal to 10 μm or more and equal to 60 μm or less. When each of the diameters D1 to Dn of the plurality of lens patterns L1 to Ln is less than 10 μm, it is difficult to manufacture the plurality of lens patterns L1 to Ln to be distinguished, and when each of the diameters D1 to Dn of the plurality of lens patterns L1 to Ln exceeds 60 μm, each of the plurality of lens patterns L1 to Ln can be visually recognized, and furthermore, Moire, a pattern having regularity, can be visually recognized by a regular arrangement of each of the plurality of lens patterns L1 to Ln and the light emitting element layer 120 (see FIG. 2).

Meanwhile, although not shown in detail, since the plurality of lens patterns L1 to Ln are different from each other or have a different diameters D1 to Dn, the plurality of lens patterns L1 to Ln can have different heights from each other. In this case, the height-diameter ratio of each of the plurality of lens patterns L1 to Ln can be equal to 20% or more and equal 50% or less. In this case, the height-diameter ratio can be defined as a ratio of the height (see H1 to Hn of FIG. 4A) of each of the plurality of lens patterns L1 to Ln with respect to the diameter (see D1 to Dn of FIG. 3B) of the respective one of the plurality of lens patterns L1 to Ln. When the height-diameter ratio of each of the plurality of lens patterns L1 to Ln is less than 20%, the mura pattern can be recognized, and when the height-diameter ratio of each of the plurality of lens patterns L1 to Ln exceeds 50%, it can not be easy to manufacture the plurality of lens patterns L1 to Ln.

In addition, although the drawing shows only the appearance in which each of the plurality of lens patterns L1 to Ln is in contact with an adjacent lens pattern, it is not limited thereto, and different adjacent lens patterns among the plurality of lens patterns L1 to Ln can be spaced apart from each other by a predetermined distance and can not be in contact with each other. Furthermore, some of the plurality of lens patterns L1 to Ln can overlap each other, and in this case, the overlapping different lens patterns can share some areas with each other.

The meaning that each of the plurality of lens patterns L1 to Ln can be irregularly disposed in an atypical form can be defined in a form in which the central points MP1 to MPn of the plurality of lens patterns L1 to Ln can or can not be positioned on the same line, in which the diameters D1 to Dn of the plurality of lens patterns L1 to Ln can be the same or can not be the same, and in which the adjacent different lens patterns of the plurality of lens patterns L1 to Ln can contact each other or can be spaced apart from each other without contacting each other. Meanwhile, in the present disclosure, the configuration irregularly disposed in an atypical form is not applied only to the plurality of lens patterns L1 to Ln, but can be applied to all other configurations in the same meaning.

According to an embodiment of the present disclosure, since the plurality of lens patterns L1 to Ln are irregularly disposed in an irregular form, the mura pattern formed when light introduced from the outside of the organic light emitting display apparatus of the present disclosure is reflected by electrodes and wires provided inside the organic light emitting display apparatus, for example a rainbow mura pattern or a ring mura pattern can be suppressed or minimized.

Meanwhile, as shown in FIG. 3B, a boundary can be provided between the plurality of lens patterns L1 to Ln. In this case, the boundary can include a plurality of boundary lines TL1 to TLn and a plurality of boundary regions TA1 to TAm (in this case, m is an integer greater than or equal to 1).

In this case, each of the plurality of boundary lines TL1 to TLn can be defined as the outer periphery of each of the plurality of lens patterns L1 to Ln. For example, the first boundary line TL1 can be defined as the outer periphery of the first lens pattern L1.

Furthermore, the plurality of boundary areas TA1 to TAm can be defined as areas formed by boundary lines of three or more adjacent lens patterns among the plurality of lens patterns L1 to Ln. The plurality of boundary areas TA1 to TAm can be formed by being surrounded between the plurality of lens patterns L1 to Ln. Accordingly, each of the plurality of boundary areas TA1 to TAm do not overlap each of the plurality of lens patterns L1 to Ln.

Hereinafter, the lens connection part 420 provided to overlap the plurality of lens patterns 410 will be described with reference to FIG. 3A again. As shown in FIG. 3A, according to an embodiment of the present disclosure, the lens connection part 420 can be provided to overlap boundaries of the plurality of lens patterns 410, for example, the plurality of boundary lines TL1 to TLn and the plurality of boundary regions TA1 to TAm.

The lens connection part 420 can be irregularly disposed in an irregular shape while overlapping the boundaries of the plurality of lens patterns 410. By forming in this way, the mura pattern formed when light introduced from the outside of the organic light emitting display apparatus of the present disclosure is reflected by electrodes and wires provided inside the organic light emitting display apparatus, for example a rainbow mura pattern or a ring mura pattern can be suppressed or minimized.

The lens connection part 420 can extend along the plurality of boundary lines TL1 to TLn and the plurality of boundary regions TA1 to TAm between the plurality of lens patterns 410, and can be continuous along the plurality of boundary lines TL1 to TLn and the plurality of boundary regions TA1 to TAm without being disconnected.

The lens connection part 420 can include a plurality of convex structures LC1 to LCo (in this case, o means an integer of 1 or more).

In this case, the plurality of convex structures LC1 to LCo can be irregularly disposed in an amorphous state. The plurality of convex structures LC1 to LCo can not overlap the center points (see MP1 to MPn in FIG. 3B), respectively, of the plurality of lens patterns 410.

Since the plurality of convex structures LC1 to LCo are formed to overlap the plurality of boundary lines TL1 to TLn and the plurality of boundary regions TA1 to TAm of the plurality of lens patterns 410, the lower surface of the light guide part 400 can all be formed of a lens pattern having a predetermined convex pattern. As described above, in the organic light emitting display apparatus including the light guide part according to the embodiment of the present disclosure, occurrence of a so-called sparkle in which a partial region is brightly visually recognized and a partial region is darkly recognized due to a height difference between a plurality of lens patterns arranged in an atypical form and a plurality of concave portions provided between the plurality of lens patterns can be suppressed. This will be described in detail with reference to FIGS. 4A to 4C later.

FIG. 4A is a partial cross-sectional view illustrating a portion of the light guide part according to an embodiment of the present disclosure. In this case, FIG. 4A is a cross-sectional view taken along line II-II′ illustrated in FIG. 3A.

As shown in FIG. 4A, the light guide part 400 according to an embodiment of the present disclosure can include a plurality of lens patterns 410, a lens connection part 420, and a filling layer 430.

The light guide part 400 can include a top surface 400a and a bottom surface 400b. In this case, the bottom surface 400b of the light guide part 400 can be formed to be closer to the light emitting element layer 120 (see FIG. 2) provided in the organic light emitting display apparatus according to the embodiment of the present disclosure than the top surface 400a of the light guide part 400. For example, the top surface 400a of the light guide part 400 can be provided to be adjacent to the second substrate 500 (see FIG. 2) of the organic light emitting display apparatus according to the embodiment of the present disclosure, and the bottom surface 400b of the light guide part 400 can be provided to be adjacent to the first substrate 100 (see FIG. 2) of the organic light emitting display apparatus according to the embodiment of the present disclosure.

The plurality of lens patterns 410 can include a material having a first refractive index, and can include a convex structure extending from the bottom surface 400b toward the top surface 400a of the light guide part 400.

The plurality of lens patterns 410 can include, for example, a first lens pattern L1, a second lens pattern L2, and a third lens pattern L3, as shown in FIG. 4A. In this case, since the first lens pattern L1 to the third lens pattern L3 are irregularly arranged atypically, they can be formed with different diameters (see D1 to D3 in FIG. 3B) and different heights H1 to H3. Meanwhile, the present disclosure is not limited thereto, and the first lens pattern L1 to the third lens pattern L3 can be formed with the same diameter and different heights, or can be formed with different diameters and the same height.

By forming in this way, the mura pattern formed when light introduced from the outside of the organic light emitting display apparatus of the present disclosure is reflected by electrodes and wires provided inside the organic light emitting display apparatus, for example a rainbow mura pattern or a ring mura pattern can be suppressed or minimized.

As shown in FIG. 4A, the first lens pattern L1 to the third lens pattern L3 can have a structure formed to be convex from the bottom surface 400b toward the top surface 400a of the light guide part 400. In this case, the first lens pattern L1 to the third lens pattern L3 can have a first height H1 to a third height H3, respectively.

Furthermore, any two of the plurality of lens patterns 410 adjacent to each other can meet at one point. For example, the first lens pattern L1 can meet the second lens pattern L2 at the first point P1, and the first lens pattern L1 can meet the third lens pattern L3 at the second point P2. In this case, the first point P1 and the second point P2 can correspond to the boundary lines (see TL1 to TLn in FIG. 3B) of the plurality of lens patterns 410.

The lens connection part 420 can be provided between the plurality of lens patterns 410. The lens connection part 420 can include, for example, a first convex structure LC1 and a second convex structure LC2, the first convex structure LC1 can be provided between the first lens pattern L1 and the second lens pattern L2, and the second convex structure LC2 can be provided between the first lens pattern L1 and the third lens pattern L3. By forming in this way, the first convex structure LC1 can be in contact with a portion of the convex surface of the first lens pattern L1 and a portion of the convex surface of the second lens pattern L2, and the second convex structure LC2 can be in contact with a portion of the convex surface of the first lens pattern L1 and a portion of the convex surface of the third lens pattern L3.

The first convex structure LC1 can overlap the first point P1, which is a point at which the first lens pattern L1 and the second lens pattern L2 meet each other. Likewise, the second convex structure LC2 can overlap the second point P2, which is a point at which the first lens pattern L1 and the third lens pattern L3 meet each other.

A height of any part of the lens connection part 420 from the bottom surface 400b toward the top surface 400a of the light guide part 400 can be less than a height of each of the plurality of lens patterns 410 from the bottom surface 400b toward the top surface 400a of the light guide part 400. For example, a height of the first convex structure LC1 from the bottom surface 400b toward the top surface 400a of the light guide part 400 can be less than a first height H1 of the first lens pattern L1 and a second height H2 of the second lens pattern L2, from the bottom surface 400b toward the top surface 400a of the light guide part 400, which are provided to be in contact with the first convex structure LC1.

The plurality of lens patterns 410 and the lens connection part 420 can form a plurality of concave portions CP1 to CPn, while being in contact with each other. For example, while the first lens pattern L1 and the first convex structure LC1 are in contact with each other, a first concave portion CP1 can be formed at the boundary between the first lens pattern L1 and the first convex structure LC1. Likewise, while the second lens pattern L2 and the first convex structure LC1 are in contact with each other, a second concave portion CP2 can be formed at the boundary between the second lens pattern L2 and the first convex structure LC1.

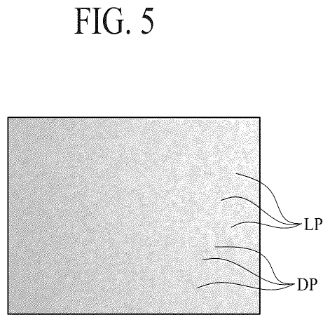

In the conventional case, since the lens connection part 420 is not provided, a concave portion was formed between the plurality of lens patterns. Therefore, the height difference between the height at the highest point of each of the plurality of lens patterns and the height of the concave portion formed between the plurality of lens patterns is increased, and as a result, there was a problem that Sparkle was recognized due to the contrast difference between the light reflected at the highest point of each of the plurality of lens patterns and the light reflected at the concave portion. Specifically, referring to FIG. 5, the light reflected at the highest point of each of the plurality of lens patterns is brightly recognized so that the bright portion LP is visually recognized, and the light reflected at the concave portion provided between the plurality of lens patterns is visually recognized darkly, and the dark portion DP is visually recognized in the actual organic light emitting display apparatus.

According to an embodiment of the present disclosure, since the lens connection part 420 is provided between the plurality of lens patterns 410, a height difference between the highest point of each of the plurality of lens patterns 410 and each of the plurality of concave portions CP1 to CPn provided between the plurality of lens patterns 410 and the lens connection part 420 is reduced.

Specifically, a first height difference ΔH1 from the first concave portion CP1 to the highest point of the first lens pattern L1 can be formed to be smaller than the first height H1, which is a height from the bottom surface 400b of the light guide part 400 to the highest point of the first lens pattern L1, and a second height difference ΔH2 from the second concave portion CP2 to the highest point of the second lens pattern L2 can be formed to be smaller than the second height H2, which is a height from the bottom surface 400b of the light guide part 400 to the highest point of the second lens pattern L2. By forming in this way, the height deviation of the light guide part 400 according to an embodiment of the present disclosure is reduced to reduce the difference in contrast of the reflected light according to the height difference, so that a sparkle cannot be generated or can be minimized.

The lens connection part 420 can be formed of the same material as the plurality of lens patterns 410. Thus, the lens connection part 420 can be provided to have the same refractive index as the plurality of lens patterns 410. Thus, the lens connection part 420 can have the same first refractive index as the plurality of lens patterns 410.

The lens connection part 420 can be provided with a size smaller than that of the plurality of lens patterns 410. In detail, each of the diameters of a plurality of convex structures LC1 to LCn of the lens connection part 420 can be less than each of the diameters (see D1 to Dn of FIG. 3B) of the plurality of lens patterns 410. In this case, the diameters DC1 to DCn of the plurality of convex structures LC1 to LCn can be defined as the distance between the plurality of adjacent concave portions CP1 to CPn. For example, the diameter DC1 of the first convex structure LC1 can be defined as the distance between the first concave portion CP1 provided between the first lens pattern L1 and the first convex structure LC1 and the second concave portion CP2 provided between the second lens pattern L2 and the first convex structure LC1. The diameter DC1 of the first convex structure LC1 can be less than the first diameter D1 of the first lens pattern L1 and the second diameter D2 of the second lens pattern L2.

Likewise, the diameter DC2 of the second convex structure LC2 can be defined as the distance between the third concave portion CP3 provided between the first lens pattern L1 and the second convex structure LC2 and the fourth concave portion CP4 provided between the third lens pattern L3 and the second convex structure LC2. The diameter DC2 of the second convex structure LC2 can be less than the first diameter D1 of the first lens pattern L1 and the third diameter D3 of the third lens pattern L3.

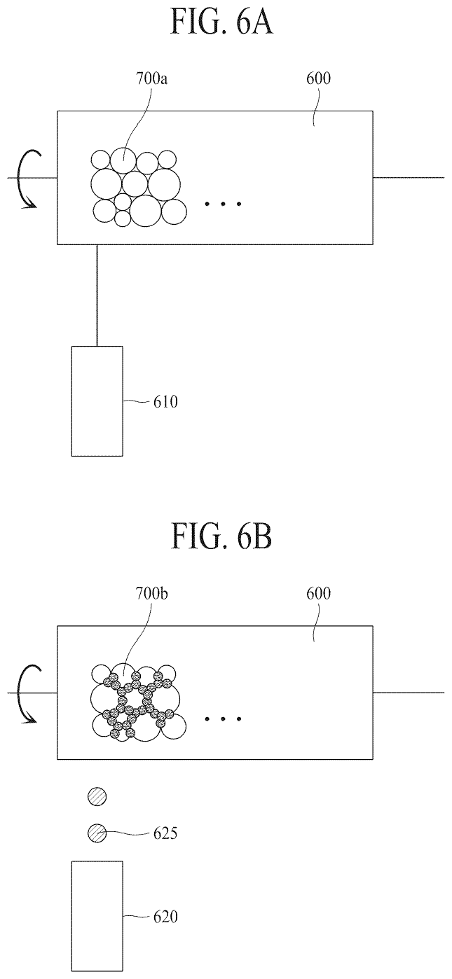

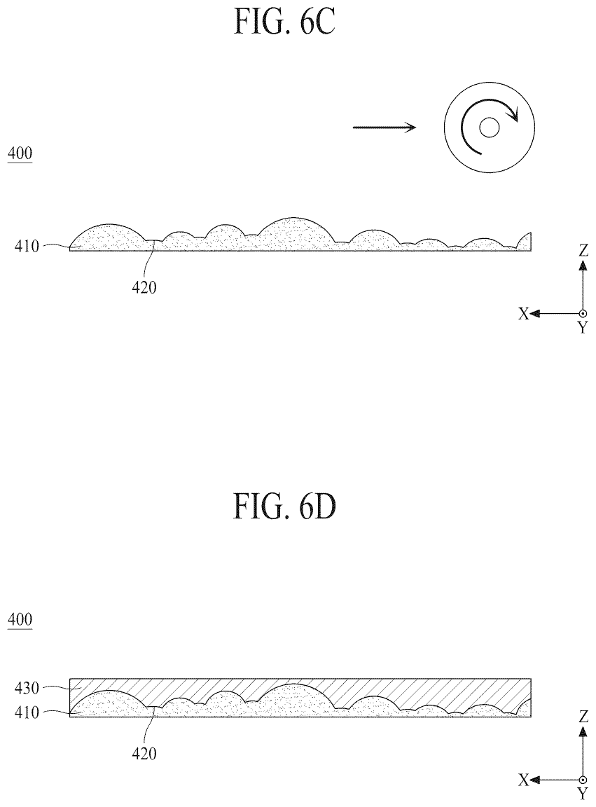

On the other hand, the radius of curvature of each of the plurality of convex structures LC1 to LCo of the lens connection part 420 can be greater than the radius of curvature of each of the plurality of lens patterns L1 to Ln. For example, a radius of curvature of any one of the plurality of convex structures can be equal to 10 μm or more and equal to 90 μm or less. As described above, the lens connection part 420 can be provided between the plurality of lens patterns 410. Meanwhile, this will be described in detail with reference to FIGS. 6A to 6D.

According to an embodiment of the present disclosure, the sum of the height (H1 to Hn) of each of the plurality of lens patterns L1 to Ln and the height of each of the plurality of concave portions CP1 to CPn can be equal to 0.5 μm or more and equal to 15 μm or less. When the sum of the height (H1 to Hn) of each of the plurality of the lens patterns L1 to Ln and the height of each of the plurality of concave portions CP1 to CPn is less than 0.5 μm, a sparkle is visually recognized, or a mura pattern is visually recognized by diffraction and interference of wavelengths, and when the sum of the height (H1 to Hn) of each of the plurality of lens patterns L1 to Ln and the height of each of the plurality of concave portions CP1 to CPn exceeds 15 μm, the height of each of the plurality of concave portions CP1 to CPn are formed to increase, causing a problem in that a sparkle is visually recognized. Meanwhile, the sum of the height (H1 to Hn) of each of the plurality of lens patterns L1 to Ln and the height of each of the plurality of concave portions CP1 to CPn is preferably equal to 0.8 μm or more and equal to 13 μm or less.

The filling layer 430 can be provided on the plurality of lens patterns 410 and the lens connection part 420 and can form the upper surface 400a of the light guide part 400. The filling layer 430 can be configured to cover the plurality of lens patterns 410 and the upper surface of the lens connection part 420. The filling layer 430 can include a material having the second refractive index. In this case, the second refractive index of the filling layer 430 can be greater than the first refractive index of the plurality of lens patterns 410 and the lens connection part 420. For example, the difference between the second refractive index and the first refractive index can be greater than or equal to 0.05 and less than or equal to 0.10.

When the difference between the first refractive index and the second refractive index is less than 0.05, Sparkle can be visually recognized and distortion can occur in the image, and when the difference between the first refractive index and the second refractive index exceeds 0.10, material reliability can be deteriorated between the plurality of lens patterns 410, the lens connection part 420 and the filling layer 430, and thus it can be difficult to easily manufacture the light guide part 400.

According to an embodiment of the present disclosure, the light guide part 400 can include the plurality of lens patterns 410 and the lens connection part 420 having the first refractive index, and the filling layer 430 having the second refractive index, so that a phenomenon in which a mura pattern formed by reflecting external light from the inside of the display apparatus is visually recognized can be removed or minimized.

FIG. 4B is a partial cross-sectional view illustrating a portion of the light guide part according to an embodiment of the present disclosure. In this case, FIG. 4B is a cross-sectional view taken along line III-III′ illustrated in FIG. 3A. Meanwhile, an embodiment of FIG. 4B is the same as an embodiment of FIG. 4A except for the configuration of the lens connection part, and thus different configurations will be mainly described below.

As shown in FIG. 4B, the light guide part 400 according to an embodiment of the present disclosure can include the plurality of lens patterns 410, the lens connection part 420, and the filling layer 430.

The plurality of lens patterns 410 can include, for example, a fourth lens pattern L4 and a fifth lens pattern L5. According to an embodiment of the present disclosure, the fourth lens pattern L4 and the fifth lens pattern L5 can be provided to be spaced apart from each other by a predetermined distance. Specifically, in the cross-sectional view, the third point P3 at which the outer periphery of the fourth lens pattern L4 meets the bottom surface 400b of the light guide part 400, and the outer periphery of the fourth point P4 at which the fifth lens pattern L5 meets the bottom surface 400b of the light guide part 400 can be spaced apart from each other unlike the case of FIG. 4A.

The lens connection part 420 can be provided between the plurality of lens patterns 410. Specifically, the third convex structure LC3 of the lens connection part 420 can be provided between the fourth lens pattern L4 and the fifth lens pattern L5, and in this case, the third convex structure LC3 can be in contact with a portion of the convex surface of the fourth lens pattern L4 and a portion of the convex surface of the fifth lens pattern L5.

According to an embodiment of the present disclosure, the third convex structure LC3 can be in contact with the bottom surface 400b of the light guide part 400. By forming in this way, the third convex structure LC3 can overlap the boundary regions (see TA1 to TAm in FIG. 3B) provided between the plurality of lens patterns 410. Furthermore, the sum of the bottom surface of the fourth lens pattern L4, the bottom surface of the fifth lens pattern L5, and the bottom surface of the third convex structure LC3 can be the same as the bottom surface 400b of the light guide part 400.

As the third convex structure LC3 is provided, a fifth concave portion CP5 can be provided between the third convex structure LC3 and the fourth lens pattern L4, and a sixth concave portion CP6 can be provided between the third convex structure LC3 and the fifth lens pattern L5.

According to an embodiment of the present disclosure, since the lens connection part 420 is provided between the plurality of lens patterns 410, a height difference between the highest point of each of the plurality of lens patterns 410 and each of the plurality of the concave portion (CP5 and CP6) provided between the plurality of lens patterns 410 and the lens connection part 420 can be reduced.

Specifically, since the third height difference ΔH3 from the fifth concave portion CP5 to the highest point of the fourth lens pattern L4 is formed to be smaller than the fourth height H4, which is the height from the bottom surface 400b of the light guide part 400 to the highest point of the fourth lens pattern L4, the height deviation of the light guide part 400 according to the embodiment of the present disclosure is reduced, and thus the contrast difference of the reflected light is reduced according to the height difference, thereby eliminating or minimizing a sparkle. Meanwhile, the relationship between the sixth concave portion CP6 and the fifth lens pattern L5 is the same as the relationship between the fifth concave portion CP5 and the fourth lens pattern L4, thus repeated descriptions will be omitted.

FIG. 4C is a partial cross-sectional view illustrating a portion of the light guide part according to an embodiment of the present disclosure. In this case, FIG. 4C is a cross-sectional view taken along line IV-IV′ illustrated in FIG. 3A. Meanwhile, an embodiment of FIG. 4C is the same as an embodiment of FIG. 4B except for the configuration of the lens connection part, and thus different configurations will be mainly described below.

As shown in FIG. 4C, a plurality of lens patterns 410 according to an embodiment of the present disclosure can include a sixth lens pattern L6 and a seventh lens pattern L7, and the lens connection part 420 can include a fourth convex structure LC4 and a fifth convex structure LC5 overlapping each other between the plurality of lens patterns 410. The fourth convex structure LC4 and the fifth convex structure LC5 can share an area OA with each other.

Both the fourth convex structure LC4 and the fifth convex structure LC5 can be in contact with the bottom surface 400b of the light guide part 400. By forming in this way, the fourth convex structure LC4 and the fifth convex structure LC5 can overlap the boundary regions (see TA1 to TAm in FIG. 3B) provided between the plurality of lens patterns 410.

By providing the fourth convex structure LC4 and the fifth convex structure LC5, a seventh concave portion CP7 can be provided between the fourth convex structure LC4 and the sixth lens pattern L6, and an eighth concave portion CP8 can be provided between the fifth convex structure LC5 and the seventh lens pattern L7.

According to an embodiment of the present disclosure, since the lens connection part 420 can be provided between the plurality of lens patterns 410, a height difference between the height of the highest point of each of the plurality of lens patterns 410 and the height of each of the plurality of concave portions CP7 and CP8 provided between the plurality of lens patterns 410 and the lens connection part 420 can be reduced.

Specifically, since the fourth height difference ΔH4 from the seventh concave portion CP7 to the highest point of the sixth lens pattern L6 is formed to be smaller than the sixth height H6, which is the height from the bottom surface 400b of the light guide part 400 to the highest point of the sixth lens pattern L6, the height deviation of the light guide part 400 according to the embodiment of the present disclosure is reduced, and thus the contrast difference of the reflected light is reduced according to the height difference, thereby eliminating or minimizing a sparkle. Meanwhile, the relationship between the eighth concave portion CP8 and the seventh lens pattern L7 is the same as the relationship between the seventh concave portion CP7 and the sixth lens pattern L6, thus repeated descriptions thereof are omitted.

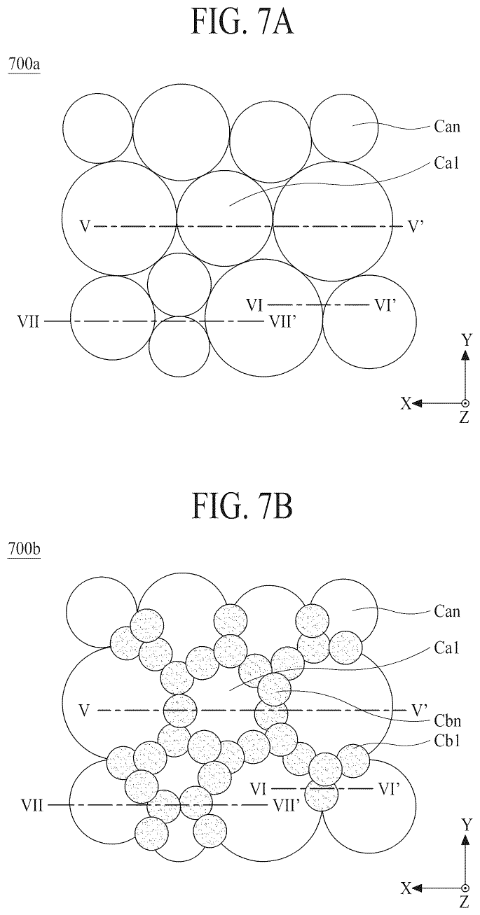

FIGS. 6A to 6D are cross-sectional views schematically illustrating a method of manufacturing a light guide part according to an embodiment of the present disclosure. and FIGS. 7A and 7B are schematic views of a surface of a mold for forming a light guide part according to an embodiment of the present disclosure, and in this case, FIG. 7A relates to the surface of the mold shown in FIG. 6A, and FIG. 7B relates to the surface of the mold shown in FIG. 6B.

First, as shown in FIGS. 6A and 7A, a first pattern 700a can be formed by irradiating a laser formed by a laser irradiation device 610 onto a surface of a mold 600 for forming the light guide part 400 according to an embodiment of the present disclosure. In this case, the first pattern 700a can be formed to be concave from a surface of the mold 600.

The first pattern 700a can include a plurality of first concave patterns Ca1 to Can, and in this case, each of the plurality of first concave patterns Ca1 to Can can be provided in a circular shape on a plane. However, the shape of each of the plurality of concave patterns Ca1 to Can is not limited thereto, and can be provided in various shapes according to the level of the art.

The plurality of first concave patterns Ca1 to Can of the first pattern 700a can be irregularly disposed in an amorphous state. Meanwhile, according to an embodiment of the present disclosure, a plurality of first concave patterns Ca1 to Can of the first pattern 700a can correspond to the plurality of lens patterns (see L1 to Ln of FIG. 3B), respectively.

Meanwhile, although not shown in detail, a first pattern 700a can be formed by irradiating a laser formed from the laser irradiation device 610 on a surface of the mold 600 to form a predetermined pattern, and then etching the predetermined pattern using an etchant. In this case, the predetermined pattern can be formed to have a size smaller than a size of the first pattern 700a.

Next, as shown in FIGS. 6B and 7B, a second pattern 700b can be formed by blasting a plurality of beads 625 on the surface of the mold 600 on which the first pattern 700a is formed. Specifically, by forming a plurality of second concave patterns Cb1 to Cbn on the first pattern 700a, the second pattern 700b can be formed.

According to an embodiment of the present disclosure, the plurality of second concave patterns Cb1 to Cbn can be irregularly disposed in an amorphous state. A size and a shape of the plurality of beads 625 can be selected so as to be blown only to a boundary region between the plurality of first concave patterns Ca1 to Can of the first pattern 700a.

The plurality of beads 625 can have a cross-section of a circle, an ellipse, or a polygon with a square or more.

Each of the plurality of beads 625 can be selected with a size larger than the size of each of the plurality of the first concave patterns Ca1 to Can of the first pattern 700a. For example, each of the plurality of beads 625 can have a size of 10 μm or more and 90 μm or less. In this case, a size of the bead 625 can mean a diameter when the bead 625 is circular, a minimum diameter when the bead 625 is oval, and a maximum distance from one surface to the other surface of the polygon when the surface of the bead is a polygon other than a curved surface.

According to an embodiment of the present disclosure, since the size of each of the plurality of beads 625 is larger than that of each of the plurality of first concave patterns Ca1 to Can of the first pattern 700a, the plurality of beads 625 can be blown only at the boundary of the plurality of first concave patterns of the first pattern 700a, and the plurality of beads 625 can not be blown inside each of the plurality of first concave patterns Ca1 to Can.

Therefore, as shown in FIG. 7B, a plurality of second concave patterns Cb1 to Cbn can be formed at the boundary of the plurality of first concave patterns of the first pattern 700a. Therefore, a radius of curvature of each of the plurality of second concave patterns Cb1 to Cbn formed by the plurality of beads 625 can be formed to be greater than a radius of curvature of each of the plurality of first concave patterns Ca1 to Can.

The plurality of beads 625 can include any one material among SiO2, Al2O3, Na2O, MgO, CaO, K2O, and TiO2. Since the plurality of beads 625 include the material described above, the plurality of beads 625 can not be broken even while colliding with the mold 600 during the blasting process.

The second pattern 700b formed in the mold 600 by the blasting process can correspond to a plurality of lens patterns (see 410 of FIG. 3A) and a lens connection part (see 420 of FIG. 3A) according to the embodiment of FIG. 3A.

Next, as shown in FIG. 6C, a plurality of lens patterns 410 and a lens connection part 420 of the light guide part 400 according to an embodiment of the present disclosure can be formed using the mold 600. In this case, the mold 600 can be provided in a cylindrical shape, and the same pattern can be formed on a material every time the mold 600 rotates on the material for forming the plurality of lens patterns 410 and the lens connection part 420. Meanwhile, a shape of the mold 600 is not limited to a cylindrical shape, and can be provided in a plate shape and pressed on a lens forming material, thereby forming the plurality of lens patterns 410 and the lens connection part 420.

According to an embodiment of the present disclosure, the plurality of first concave patterns Ca1 to Can of the second pattern 700b can correspond to a plurality of lens patterns 410 according to an embodiment of the present disclosure, and the plurality of second concave patterns Cb1 to Cbn of the second pattern 700b can correspond to the lens connection part 420 according to an embodiment of the present disclosure.

Finally, as shown in FIG. 6D, a light guide part 400 according to an embodiment of the present disclosure can be manufactured by applying a filling layer 430 having a refractive index greater than that of the plurality of lens patterns 410 and the lens connection part 420 formed using the mold 600.

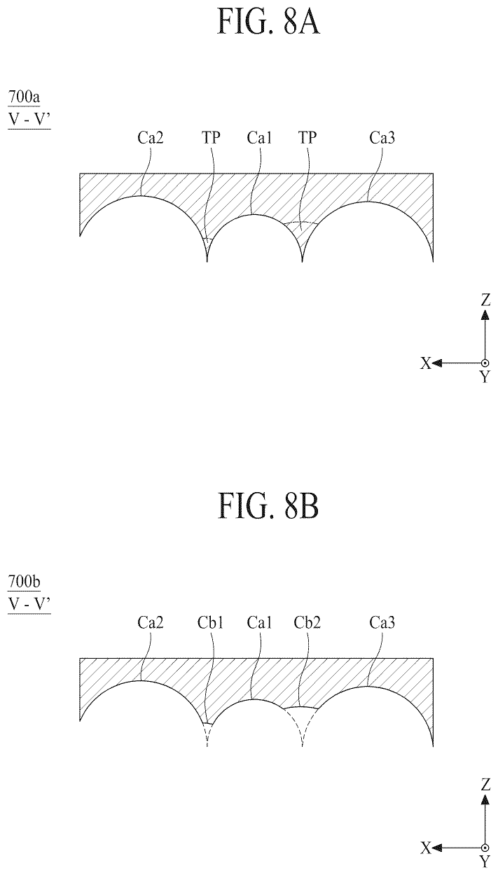

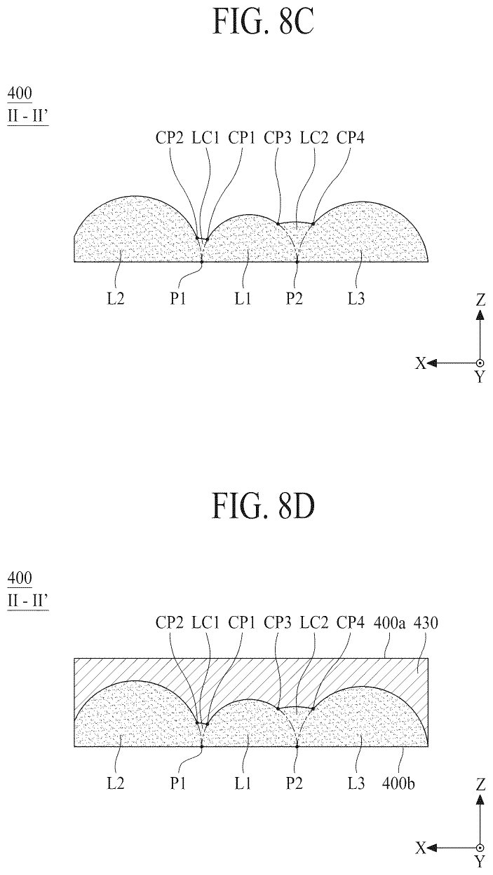

FIGS. 8A to 8D are partial cross-sectional views schematically illustrating a method of manufacturing a light guide part according to an embodiment of the present disclosure. In this case, FIGS. 8A and 8B are partial cross-sections taken along line V-V′ illustrated in FIGS. 7A and 7B, respectively, and FIGS. 8C and 8D are partial cross-sections taken along line II-II′ illustrated in FIG. 3A.

First, as illustrated in FIG. 8A, a surface of the mold 600 can be patterned by the laser irradiation device 610 to form a first pattern 700a. In this case, the first pattern 700a can include a plurality of first concave patterns Ca1 to Ca3. The plurality of first concave patterns Ca1 to Ca3 can be irregularly disposed in an amorphous state.

A plurality of tip portions TP can be provided between the plurality of first concave patterns Ca1 to Ca3.

Next, as show in FIG. 8B, the second pattern 700b can be formed by performing a blasting process on the mold 600 on which the first pattern 700a is formed.

According to an embodiment of the present disclosure, by using the beads 625 each having a size larger than that of each of the plurality of first concave patterns Ca1 to Ca3 in the blasting process, the tip portion TP provided between the plurality of first concave patterns Ca1 to Ca3 can be removed to form a second pattern 700b including the plurality of second concave patterns Cb1 to Cb2.

Next, as shown in FIG. 8C, a plurality of lens patterns 410 and a lens connection part 420 according to an embodiment of the present disclosure can be formed using the mold 600 having the second pattern 700b formed therein, the plurality of first concave patterns Ca1 to Ca3 of the second pattern 700b can correspond to the plurality of lens patterns 410, and the plurality of second concave patterns Cb1 to Cb2 of the second pattern 700b can correspond to the lens connection part 420.

In this case, the plurality of lens patterns 410 and the lens connection part 420 can correspond to the plurality of lens patterns and the lens connection part according to an embodiment of FIG. 4A.

Finally, as shown in FIG. 8D, the light guide part 400 according to an embodiment of the present disclosure can be formed by forming the filling layer 430 on the plurality of lens patterns 410 and the lens connection part 420.

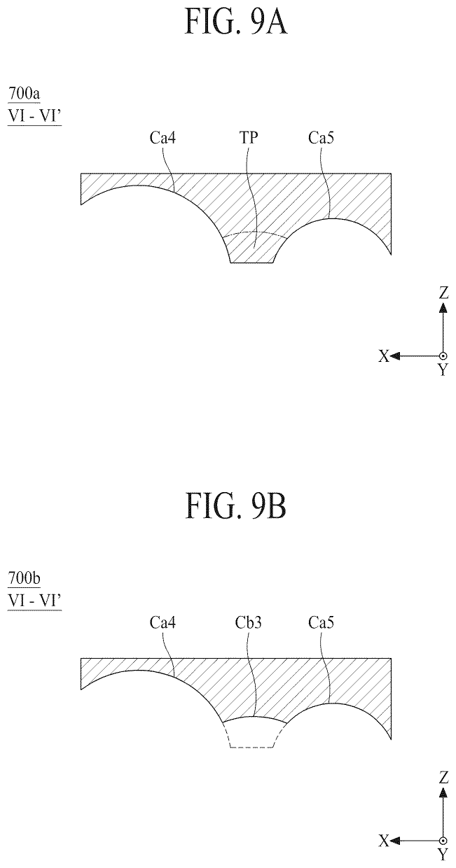

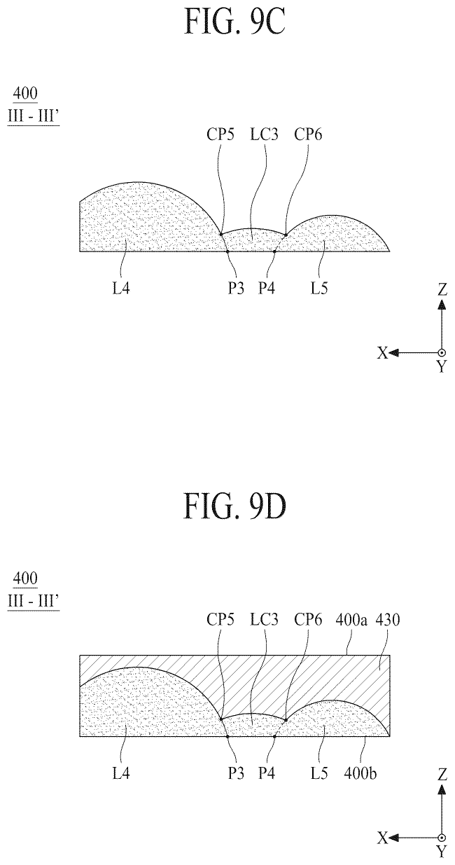

FIGS. 9A to 9D are partial cross-sectional views schematically illustrating a method of manufacturing the light guide part according to an embodiment of the present disclosure. In this case, FIGS. 9A and 9B are partial cross-sections taken along line VI-VI′ illustrated in FIGS. 7A and 7B, respectively, and FIGS. 9C and 9D are partial cross-sections taken along line III-III′ illustrated in FIG. 3A.

First, as shown in FIG. 9A, a surface of the mold 600 can be patterned by the laser irradiation device 610 to form a first pattern 700a. In this case, the first pattern 700a can include a plurality of first concave patterns Ca4 to Ca5. In this case, the plurality of first concave patterns Ca4 to Ca5 can be irregularly disposed in an irregular state.

The plurality of first concave patterns Ca4 to Ca5 can not meet each other. Specifically, the plurality of first concave patterns Ca4 to Ca5 can be formed to be spaced apart from each other by the tip portion TP provided between the plurality of first concave patterns Ca4 to Ca5.

Next, as shown in FIG. 9B, the second pattern 700b can be formed by performing a blasting process on the mold 600 on which the first pattern 700a is formed.

According to an embodiment of the present disclosure, by using the plurality of beads 625 each having a size larger than that of each of the plurality of first concave patterns Ca4 to Ca5 in the blasting process, the tip portion TP provided between the plurality of first concave patterns Ca4 to Ca5 can be removed to form a second pattern 700b including a plurality of second concave patterns Cb3.

Next, as shown in FIG. 9C, a plurality of lens patterns 410 and a lens connection part 420 according to an embodiment of the present disclosure can be formed using the mold 600 having the second pattern 700b formed therein. A plurality of first concave patterns Ca4 to Ca5 of the second pattern 700b can correspond to the plurality of lens patterns 410, and the plurality of second concave patterns Cb3 of the second pattern 700b can correspond to the lens connection part 420.

In this case, the plurality of lens patterns 410 and the lens connection part 420 can correspond to the plurality of lens patterns and the lens connection part according to an embodiment of FIG. 4B.

Finally, as shown in FIG. 9D, the light guide part 400 according to an embodiment of the present disclosure can be formed by forming the filling layer 430 on the plurality of lens patterns 410 and the lens connection part 420.

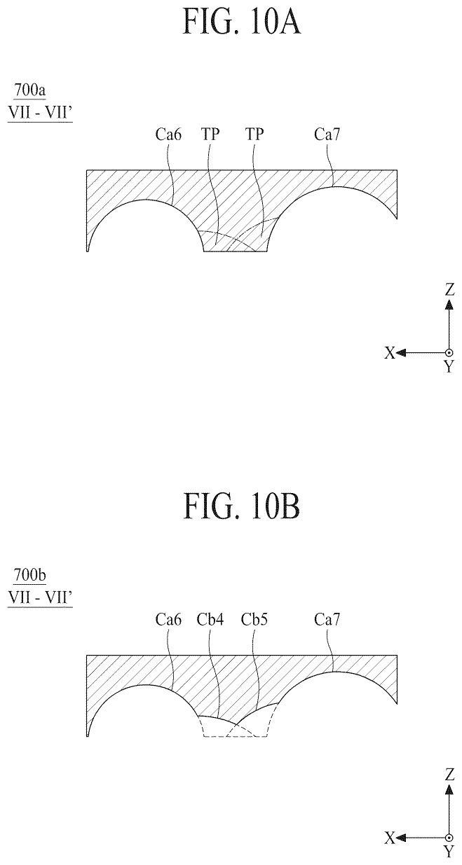

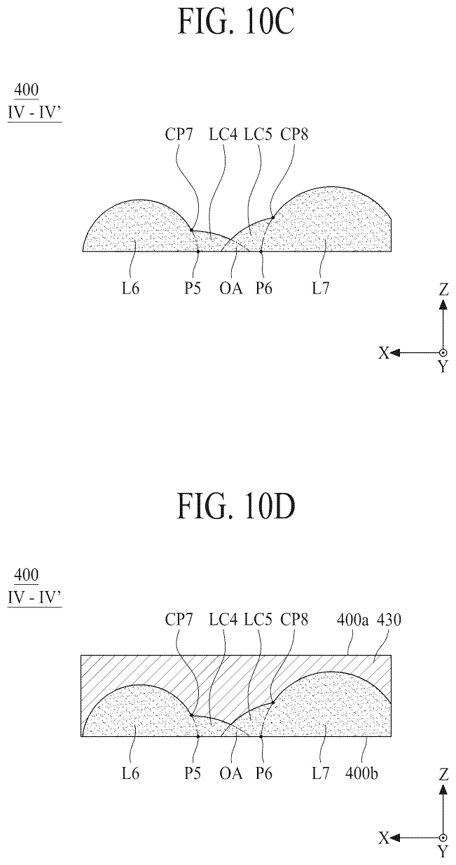

FIGS. 10A to 10D are partial cross-sectional views schematically illustrating a method of manufacturing a light guide part according to an embodiment of the present disclosure. In this case, FIGS. 10A and 10B are partial cross-sections taken along line VII-VII′ illustrated in FIGS. 7A and 7B, respectively, and FIGS. 10C and 10D are partial cross-sections taken along line IV-IV′ illustrated in FIG. 3A.

First, as shown in FIG. 10A, a surface of the mold 600 can be patterned by the laser irradiation device 610 to form a first pattern 700a. In this case, the first pattern 700a can include a plurality of first concave patterns Ca6 to Ca7. In this case, the plurality of first concave patterns Ca6 to Ca7 can be irregularly disposed in an irregular state.

The plurality of first concave patterns Ca6 to Ca7 can not meet each other. Specifically, the plurality of first concave patterns Ca4 to Ca5 can be formed to be spaced apart from each other by the tip portions TP (two shown in FIG. 10A) provided between the plurality of first concave patterns Ca4 to Ca5. In this case, some regions of the plurality of tip portions TP can overlap each other.

Next, as shown in FIG. 10B, the second pattern 700b can be formed by performing a blasting process on the mold 600 on which the first pattern 700a is formed.

According to an embodiment of the present disclosure, by using the plurality of beads 625 each having a size larger than that of each of the plurality of first concave patterns Ca6 to Ca7 in the blasting process, the tip portions TP provided between the plurality of first concave patterns Ca6 to Ca7 can be removed to form a second pattern 700b including a plurality of second concave patterns Cb4 to Cb5. Meanwhile, the plurality of second concave patterns Cb4 to Cb5 can be formed by colliding the different beads 625 in the regions provided between the plurality of first concave patterns Ca6 to Ca7 twice. Meanwhile, the plurality of second concave patterns Cb4 to Cb5 are not limited thereto, and can be formed by colliding the beads two or more times.

Next, as shown in FIG. 10C, a plurality of lens patterns 410 and a lens connection part 420 according to an embodiment of the present disclosure can be formed using the mold 600 having the second pattern 700b formed therein. A plurality of first concave patterns Ca6 to Ca7 of the second pattern 700b can correspond to the plurality of lens patterns 410, and the plurality of second concave patterns Cb4 to Cb5 of the second pattern 700b can correspond to the lens connection part 420.

In this case, the plurality of lens patterns 410 and the lens connection part 420 can correspond to the plurality of lens patterns and the lens connection part according to an embodiment of FIG. 4C.

Finally, as shown in FIG. 10D, the light guide part 400 according to an embodiment of the present disclosure can be formed by forming the filling layer 430 on the plurality of lens patterns 410 and the lens connection part 420.

FIG. 11 is a cross-sectional view of a light guide member according to another embodiment of the present disclosure.

As shown in FIG. 11, the light guide member 800 according to another embodiment of the present disclosure includes a plurality of lens patterns 810 and a filling layer 830. The filling layer 830 can form a top surface 800a of the light guide member 800.

The plurality of lens patterns 810 include a base part 811 and a pattern part 813.

The base part 811 can form a bottom surface 800b of the light guide member 800 opposite to the top surface 800a.

The base part 811 can include an acryl-based material. For example, the base part 811 can be an acrylic resin, but is not limited thereto. The base part 811 can have a first refractive index, and the first refractive index can be, for example, greater than 0 and equal to or less than 2.

The material constituting the base part 811 can be cured by, for example, light having a wavelength of any one of an ultraviolet wavelength band region and a visible light wavelength band region. Specifically, the material constituting the base part 811 can be cured by, for example, light having a wavelength of 200 nm or more and 1000 nm or less. Specifically, the material constituting the pattern part 813 can be a material that can be cured by a wavelength of light emitted from a xenon lamp, but is not limited thereto.

The base part 811 can include a concave surface from the bottom surface 800b of the light guide member 800.

The pattern part 813 can be provided on the base part 811. The pattern part 813 can be provided to cover a top surface of the base part 811. Therefore, the pattern part 813 can be provided to cover the concave surface of the base part 811.

The pattern part 813 can include a first convex surface 813a adjacent to the top surface 800a and a second convex surface 813b adjacent to the bottom surface 800b.

The first convex surface 813a and the second convex surface 813b can be provided to correspond to each other, and are formed in a convex structure from different surfaces. For example, the first convex surface 813a is formed in a convex structure from the bottom surface 800b of the light guide member 800, and the second convex surface 813b is formed in a convex structure from the top surface 800a of the light guide member 800. The second convex surface 813b of the pattern part 813 can be provided to correspond to the concave upper surface of the base part 811.

According to another embodiment of the present disclosure, external light introduced from the top surface 800a of the light guide member 800 can be prevented from being reflected by a plurality of wires and electrodes provided below the bottom surface 800b of the light guide member 800 by the first convex surface 813a of the pattern part 813, and even if the external light is reflected by the plurality of wires and electrodes included in a circuit element layer and is introduced back into the bottom surface 800b of the light guide member 800, the introduced external light can be refracted by the pattern part 813 of the light guide member 800 and attracted to be directed toward the side surface of the display device. Accordingly, a degree of reflection of external light introduced to the display device according to another embodiment of the present disclosure can be suppressed, and visibility of the user can be improved. Furthermore, black visibility of the user can be improved.

The pattern part 813 can include a material having the first refractive index. The pattern part 813 can include a material having the same refractive index as the base part 811. The first refractive index can be, for example, greater than 0 and equal to or less than 2, but the first refractive index of the material constituting the pattern part 813 is not limited thereto.

Since the base part 811 and the pattern part 813 include a material having the same refractive index, light can not be refracted even though external light or light reflected by a thin film transistor, a wiring, and an electrode provided under the bottom surface 800b of the light guide member 800 passes through a boundary surface between the base part 811 and the pattern part 813, for example, the second convex surface 813b. Therefore, the effect of improving visibility of the light guide member 800 can be prevented from being reduced by the second convex surface 813b convex from the top surface 800a of the light guide member 800.

According to an embodiment of the present disclosure, the pattern part 813 can include a material that can be sintered by light of a specific wavelength band. The pattern part 813 can include, for example, metal oxide and silicon oxide (SiO2), but is not limited thereto. When the pattern part 813 includes a metal oxide, the pattern part 813 can be formed by, for example, zinc oxide (ZnO), aluminum oxide (Al2O3), magnesium oxide (MgO), and tin oxide (Sn). The material constituting the pattern part 813 can be sintered by, for example, light of any one of an ultraviolet wavelength band region and a visible wavelength band region. Specifically, the material constituting the pattern part 813 can be sintered by, for example, light of a wavelength of 200 nm to 1000 nm. Specifically, the material constituting the pattern part 813 can be, for example, a material that can be sintered by light of a wavelength emitted from a xenon lamp, but is not limited thereto.

The pattern part 813 can include a plurality of lens structures La1 to Lan.

Some of the plurality of lens structures La1 to Lan are formed continuously with each other. For example, the first lens structure La1 and the second lens structure La2 can share a predetermined area with each other. Alternatively, the first lens structure La1 and the second lens structure La2 can be provided to overlap each other. For example, the second lens structure La2 and the third lens structure La3 can contact each other at one point, but are not limited thereto. Any two adjacent lens structures among the plurality of lens structures La1 to Lan can be spaced apart from each other. For example, the third lens structure La3 and the fourth lens structure La4 can be formed to be spaced apart from each other by a predetermined distance without overlapping or being in contact with each other.

Among the plurality of lens structures La1 to Lan, two adjacent lens structures can overlap each other, be in contact with each other, or be spaced apart from each other. As described above, a manner in which two adjacent lens structures among the plurality of lens structures La1 to Lan are formed differently can be defined as that the plurality of lens structures La1 to Lan can be irregularly arranged. According to an embodiment of the present disclosure, since the plurality of lens structures La1 to Lan are irregularly arranged, occurrence of mura patterns, for example, rainbow mura or ring mura can be prevented.

When two adjacent lens structures among the plurality of lens structures La1 to Lan overlap each other, two adjacent lens structures among the plurality of lens structures La1 to Lan can include a lens overlapping part LOa, which is an area formed to overlap each other. For example, the first lens structure La1 and the second lens structure La2 are formed to overlap each other, so that a lens overlapping part LOa can be formed between the first lens structure La1 and the second lens structure La2. According to an embodiment of the present disclosure, since the first lens structure La1 and the second lens structure La2 are formed to overlap each other, a concave first point P1′ can be formed from the bottom surface 800b of the light guide member 800 in a region of the first convex surface 813a in which the lens overlapping part LOa is formed, between the peak points of each of the first lens structure La1 and the second lens structure La2. In this case, a first height difference ΔH1′ can be formed between any one of the peak points of each of the first lens structure La1 and the second lens structure La2 and the first point P1′ in a vertical direction. According to an embodiment of the present disclosure, since the first height difference ΔH1′ is relatively smaller due to the lens overlapping part LOa than when there is no lens overlapping part LOa, the height between the peak points of each of the continuously provided first lens structure La1 and the second lens structure La2 and the first point P1′ is relatively reduced, and thus it is possible to implement a display device in which the generation of sparkles is suppressed or removed.

At least two lens structures among the plurality of lens structures La1 to Lan can have the same length in the horizontal direction and/or the same length in the vertical direction. For example, the third lens structure La3 can have a first short axis length A1′ in the vertical direction and can have a first long axis length A2′ in the horizontal direction. In this case, the vertical direction can be a direction in which the top surface 800a and the bottom surface 800b of the light guide member 800 face each other, and the horizontal direction can be a direction perpendicular to the vertical direction. In this case, the first long axis length A2′ can be provided to be greater than the first short axis length A1′. Furthermore, the first short axis length A1′ can mean the shortest distance between an uppermost point and a lowermost point of any one of the plurality of lens structures La1 to Lan, and the first long axis length A2′ can mean the shortest distance between a left end and a right end of any one of the plurality of lens structures La1 to Lan.

According to an embodiment of the present disclosure, each of the first lens structure La1, the second lens structure La2, the third lens structure La3, and the fourth lens structure La4 can have the same first short axis length A1′ in the vertical direction, but the present disclosure is not limited thereto, and any one of the plurality of lens structures La1 to Lan can have a length in the vertical direction different from the first short axis length A1′.

According to an embodiment of the present disclosure, two or more lens structures among the plurality of lens structures La1 to Lan can have the same shape. Specifically, two or more lens structures among the plurality of lens structures La1 to Lan can have an elliptical shape. For example, the first lens structure La1 and the second lens structure La2 can have the same elliptical shape. However, since the first lens structure La1 and the second lens structure La2 are provided to overlap each other, the first lens structure La1 and the second lens structure La2 share the lens overlapping part LOa. For example, the second lens structure La2 and the third lens structure La3 can have the same elliptical shape, but are not limited thereto, and any one of the lens structures La1 to Lan can have a shape other than an elliptical shape, for example, a spherical shape.

The filling layer 830 can be provided on the plurality of lens patterns 810 and can form a top surface 800a of the light guide member 800. The filling layer 830 can be configured to surround the top surface of the plurality of lens patterns 810. In detail, the filling layer 830 can include a material having a second refractive index. In this case, the second refractive index of the filling layer 830 can be greater than the first refractive index of the plurality of lens patterns 810. For example, a difference between the second refractive index and the first refractive index can be 0.05 or more and 0.10 or less.

When the difference between the first refractive index and the second refractive index is less than 0.05, Sparkle can be visually recognized and distortion can occur in the image, and when the difference between the first refractive index and the second refractive index exceeds 0.10, material reliability between the plurality of lens patterns 810 and the filling layer 830 can be reduced, making it difficult to easily manufacture the light guide member 800.

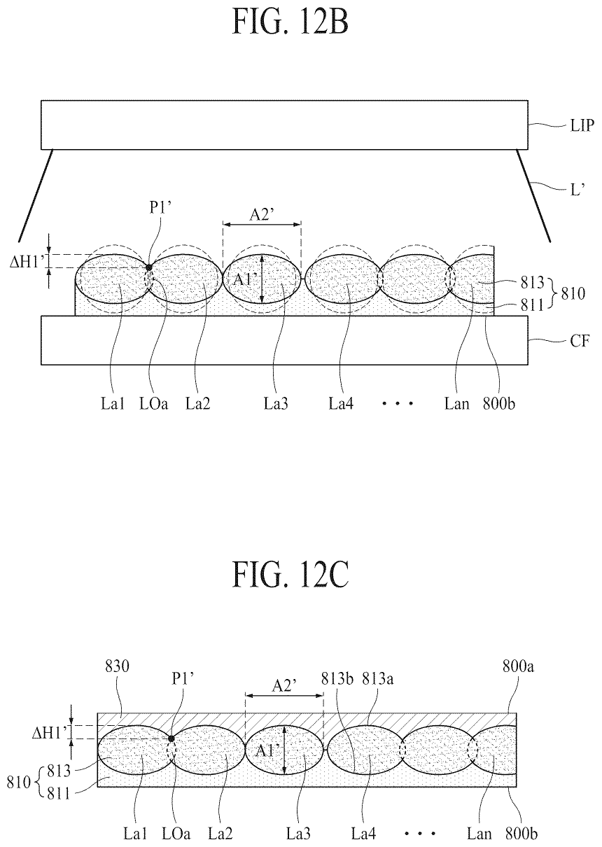

FIGS. 12A to 12C are cross-sectional views schematically illustrating a process of manufacturing a light guide member according to another embodiment of the present disclosure. Particularly, the cross-sectional views of FIGS. 12A to 12C relate to an embodiment of FIG. 11, and the same reference numerals are assigned to the same configurations, and repeated descriptions thereof will be omitted or may be briefly provided.

First, as shown in FIG. 12A, a resin composition 815 can be applied onto the carrier film CF. Specifically, the resin composition 815 can be applied on one surface, for example, a top surface of the carrier film CF.

The resin composition 815 can be a flowable material having a viscosity equal to or higher than a predetermined level. Therefore, even when the resin composition 815 is applied to one surface of the carrier film CF, the resin composition 815 can not deviate from the carrier film CF.

The resin composition 815 includes a curable material 815a and a sintering material 815b. Specifically, the sintering material 815b is dispersed in or on the surface of the curable material 815a. Since the resin composition 815 includes the curable material 815a and the sintering material 815b dispersed in or on the surface of the curable material 815a, the sintering material 815b dispersed in the resin composition 815 can be irregularly disposed when the resin composition 815 is applied to the carrier film CF.

The curable material 815a can include a photo-curable material. However, the present disclosure is not limited thereto. The curable material 815a can include a material that is cured by light in a visible light wavelength band region or an ultraviolet wavelength band region, for example. Specifically, the curable material 815a can be cured by light having a wavelength of, for example, 200 nm or more and 1000 nm or less. The curable material 815a can be, for example, an acrylic resin, but is not limited thereto. The curable material 815a can be cured by, for example, a xenon lamp.

The sintering material 815b can be dispersed in the curable material 815a. The sintering material 815b can be sintered by light irradiation, but is not limited thereto.

The sintering material 815b can be a spherical particle, but is not limited thereto, or the sintering material 815b can be an elliptical particle. When the sintering material 815b is a spherical particle, the sintering material 815b can have a diameter greater than 0 and less than or equal to 90 μm. Alternatively, when the sintering material 815b is an elliptical particle, the sintering material 815b can have a major axis diameter greater than or equal to 0 and less than or equal to 90 μm. The sintering material 815b can be, for example, a plurality of spherical or elliptical particles having the same size.

The sintering material 815b can be sintered by light in a visible light wavelength band region or an ultraviolet wavelength band region, for example. Specifically, the sintering material 815b can be sintered by light having a wavelength of, for example, 200 nm or more and 1000 nm or less. The sintering material 815b can be sintered by, for example, a xenon lamp.

The sintering material 815b can include a material sintered by light in the visible light wavelength band region or the ultraviolet wavelength band region. For example, the sintering material 815b can include a metal oxide or silicon oxide (SiO2), but is not limited thereto. When a metal oxide is used as the sintering material 815b, the sintering material 815b can include, for example, at least one of zinc oxide (ZnO), aluminum oxide (Al2O3), magnesium oxide (MgO) and tin oxide (SnO2).

Next, as shown in FIG. 12B, light L′ of a predetermined wavelength band can be irradiated onto the resin composition 815 by using a light irradiation part LIP. In this case, the resin composition 815 can be cured to form a plurality of lens patterns 810.

The light L′ irradiated to the resin composition 815 can be light of a wavelength band for transforming the curable material 815a and the sintering material 815b included in the resin composition 815.

The light L′ can be, for example, light in an ultraviolet wavelength band and a visible light wavelength band. Specifically, the light L′ can be, for example, light having a wavelength equal to or greater than 200 nm and equal to or less than 1000 nm. The light L′ can be, for example, light generated from a xenon Xe lamp. The intensity of the light L′ can be 500 mJ/cm2 or more and less than 1000 mJ/cm2. In this case, the intensity of the light L′ can be the total energy intensity required to form the resin composition 815 in the plurality of lens patterns 810. When the intensity of the light L′ is less than 500 mJ/cm2, the first convex surface (see 813a in FIG. 11) for removing the mura pattern can not be formed due to insufficient curing of the curable material 815a or sintering of the sintering material 815b, and when the intensity of the light L′ exceeds 1000 mJ/cm2, a refractive index can be changed due to damage to a partial area of the curable material 815a, and the sintering material 815b can be too sintered to flatten the first convex surface (see 813a in FIG. 11), and eventually, the mura pattern can not be reduced or removed.

According to another embodiment of the present disclosure, when the light L′ generated by the light irradiation part LIP is irradiated to the resin composition 815, the curable material 815a in the resin composition 815 can be cured by the light L′, and the sintering material 815b can be sintered from each other by the light L′. In this case, in a case in which the sintering material 815b is a spherical particle, the sintering material 815b can have a length in the vertical direction and a length in the horizontal direction, respectively. Specifically, the sintering material 815b can overlap adjacent sintering materials 815b while being sintered, and the length of the sintering material 815b in the vertical direction can be shorter than the length in the horizontal direction. However, the present disclosure is not limited thereto.

As the curable material 815a is cured and the sintering material 815b is sintered, the curable material 815a can become the base part 811, and the sintering material 815b can become the pattern part 813. Thus, the resin composition 815 can be a plurality of lens patterns 810 according to another embodiment of the present disclosure by the light L′ irradiated from the light irradiation part LIP.

Finally, as shown in FIG. 12C, when the filling layer 830 is applied on the plurality of lens patterns 810 and the carrier film CF provided under the plurality of lens patterns 810 is removed, the light guide member 800 according to another embodiment of the present disclosure can be realized. When the light guide member 800 is manufactured according to another embodiment of the present disclosure, since the plurality of lens patterns 810 are formed using the resin composition 815 in which the curable material 815a and the sintering material 815b are mixed, the manufacturing time of the light guide member 800 can be shortened.

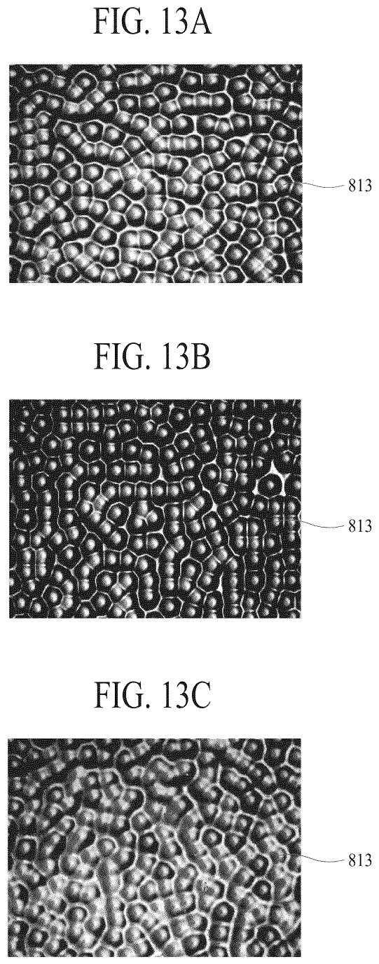

FIGS. 13A to 13C are examples of planar TEM photographs of the light guide member 800 according to another embodiment of the present disclosure. Particularly, FIGS. 13A to 13C show a sintering material having a diameter of 20 μm. For example, FIG. 13A shows a case where the intensity of the light formed in the light irradiation part is 500 mJ/cm2, FIG. 13B shows a case where the intensity of the light formed in the light irradiation part is 750 mJ/cm2, and FIG. 13C shows a case where the intensity of the light formed in the light irradiation part is 1000 mJ/cm2.

As shown in FIGS. 13A to 13C, the sintering materials (see 815b in FIG. 12A) can be sintered by the light irradiated from the light irradiation part (see LIP in FIG. 12B) to overlap each other. In this case, the sintering materials (see 815b in FIG. 12A) to overlap each other by sintering can form the pattern part 813 of the light guide member 800 according to another embodiment of the present disclosure. The energy intensity of the light (see L′ in FIG. 12B) for forming the pattern part 813 can be variously adjusted. In this case, as the energy intensity of the light (see L′ in FIG. 12B) increases, the sintering material (see 815b in FIG. 12A) to form the pattern part 813 can be further sintered. Accordingly, as shown in an embodiment of FIGS. 13A to 13C, as the intensity of the light (see L′ in FIG. 12B) increases, the degree to which the sintering material (see 815b in FIG. 12A) is sintered increases, and thus, the roughness Ra of the pattern part 813 can sequentially decrease to 1.770 μm, 1.273 μm, and 1.053 μm, respectively. Accordingly, it can be confirmed that the roughness Ra of the pattern part 813 can be adjusted by adjusting the intensity of the light (see L′ in FIG. 12B) of the light irradiation part (see LIP in FIG. 12B).

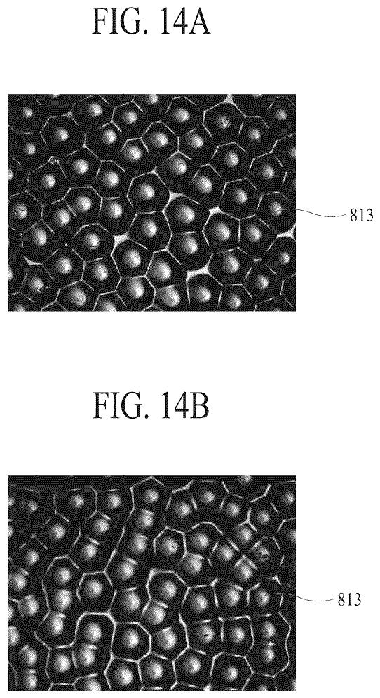

FIGS. 14A and 14B are examples of planar TEM photographs of a light guide member 800 according to another embodiment of the present disclosure. In this case, FIGS. 14A and 14B show a sintering material having a diameter of 35 μm. Particularly, FIG. 14A shows a case where the intensity of the light (see L′ in FIG. 12B) formed by the light irradiation part (see LIP in FIG. 12B) is 500 mJ/cm2, and FIG. 14B shows a case where the intensity of the light (see L′ in FIG. 12B) formed by the light irradiation part (see LIP in FIG. 12B) is 750 mJ/cm2.

As shown in FIGS. 14A and 14B, the sintering material (see 815b of FIG. 12A) can be sintered by the light irradiated from the light irradiation part (see LIP in FIG. 12B) to overlap each other. In this case, the sintering material (see 815b in FIG. 12A) to overlap each other can form the pattern part 813 of the light guide member 800 according to another embodiment of the present disclosure. The energy intensity of the light (see L′ in FIG. 12B) for forming the pattern part 813 can be variously adjusted. In this case, as the energy intensity of the light (see L′ in FIG. 12B) increases, the sintering material (see 815b in FIG. 12A) for forming the pattern part 813 can be further sintered. Accordingly, as shown in the embodiments of FIGS. 14A and 14B, as the intensity of the light (see L′ in FIG. 12B) increases, the degree to which the sintering material (see 815b in FIG. 12A) is sintered increases, and thus, the roughness Ra of the pattern part 813 can sequentially decrease to 2.717 μm and 2.368 μm. In addition, referring to FIGS. 13A to 13C together, it can be seen that the roughness Ra of the pattern part 813 according to another embodiment of the present disclosure can be adjusted by differently adjusting the size of the sintering material (see 815b in FIG. 12A).

FIG. 15 is a cross-sectional view of a light guide member according to another embodiment of the present disclosure.

As shown in FIG. 15, the light guide member 900 according to another embodiment of the present disclosure includes a plurality of lens patterns 910 and a filling layer 930. The filling layer 930 can form a top surface 900a of the light guide member 900.

The plurality of lens patterns 910 include a base part 911 and a pattern part 913.

The base part 911 can form a bottom surface 900b of the light guide member 900 opposite to the top surface 900a.

The base part 911 can include an acryl-based material. For example, the base part 911 can be an acrylic resin, but is not limited thereto. The base part 911 can have a first refractive index, and the first refractive index can be, for example, greater than 0 and equal to or less than 2.

The material constituting the base part 911 can be cured by, for example, light having a wavelength of any one of an ultraviolet wavelength band region and a visible light wavelength band region. Specifically, the material constituting the base part 911 can be cured by, for example, light having a wavelength of 200 nm or more and 1000 nm or less. Specifically, the material constituting the pattern part 913 can be a material that can be cured by a wavelength of light emitted from a xenon lamp, but is not limited thereto.

The base part 911 can include a concave surface from the bottom surface 900b of the light guide member 900.

The pattern part 913 can be provided on the base part 911. The pattern part 913 can be provided to cover the top surface of the base part 911. Therefore, the pattern part 913 can be provided to cover the concave surface of the base part 911.

The pattern part 913 can include a first convex surface 913a adjacent to the top surface 900a and a second convex surface 913b adjacent to the bottom surface 900b.

The first convex surface 913a and the second convex surface 913b can be provided to correspond to each other, and are formed in a convex structure from different surfaces. For example, the first convex surface 913a is formed in a convex structure from the bottom surface 900b of the light guide member 900, and the second convex surface 913b is formed in a convex structure from the top surface 900a of the light guide member 900. The second convex surface 913b of the pattern part 913 can be provided to correspond to the concave upper surface of the base part 911.

According to another embodiment of the present disclosure, external light introduced from the top surface 900a of the light guide member 900 can be prevented from being reflected by a plurality of wires and electrodes provided below the bottom surface 900b of the light guide member 900 by the first convex surface 913a of the pattern part 913, and even if the external light is reflected by the plurality of wires and electrodes included in a circuit element layer and is introduced back into the bottom surface 900b of the light guide member 900, the introduced external light can be refracted by the pattern part 913 of the light guide member 900 and attracted to be directed toward the side surface of the display device. Accordingly, a degree of reflection of external light introduced to the display device according to another embodiment of the present disclosure can be suppressed, and visibility of the user can be improved. Furthermore, black visibility of the user can be improved.

The pattern part 913 can include a material having the first refractive index. The pattern part 913 can include a material having the same refractive index as the base part 911. The first refractive index can be, for example, greater than 0 and equal to or less than 2, but the first refractive index of the material constituting the pattern part 913 is not limited thereto.

Since the base part 911 and the pattern part 913 include a material having the same refractive index, light can not be refracted even though external light or light reflected by a thin film transistor, a wiring, and an electrode provided under the bottom surface 900b of the light guide member 900 passes through a boundary surface between the base part 911 and the pattern part 913, for example, the second convex surface 913b. Therefore, the effect of improving visibility of the light guide member 900 can be prevented from being reduced by the second convex surface 913b convex from the top surface 900a of the light guide member 900.

According to an embodiment of the present disclosure, the pattern part 913 can include a material that can be sintered by light of a specific wavelength band. The pattern part 913 can include, for example, metal oxide and silicon oxide (SiO2), but is not limited thereto. When the pattern part 913 includes a metal oxide, the pattern part 913 can be formed by, for example, zinc oxide (ZnO), aluminum oxide (Al2O3), magnesium oxide (MgO), and tin oxide (SnO2). The material constituting the pattern part 913 can be sintered by, for example, light of any one of an ultraviolet wavelength band region and a visible wavelength band region. Specifically, the material constituting the pattern part 913 can be sintered by, for example, light of a wavelength of 200 nm to 1000 nm. Specifically, the material constituting the pattern part 913 can be, for example, a material that can be sintered by light of a wavelength emitted from a xenon lamp, but is not limited thereto.

The pattern part 913 can include a plurality of lens structures Lb1 to Lbn.

Some of the plurality of lens structures Lb1 to Lbn are formed continuously with each other. For example, the first lens structure Lb1 and the second lens structure Lb2 can share a predetermined area with each other. Alternatively, the first lens structure Lb1 and the second lens structure Lb2, the second lens structure Lb2 and the third lens structure Lb3, and the third lens structure Lb3 and the fourth lens structure Lb4 can be provided to overlap each other. Meanwhile, although not shown, any two adjacent lens structures among the plurality of lens structures Lb1 to Lbn can be in contact with each other at one point, and any two adjacent lens structures among the plurality of lens structures Lb1 to Lbn can be spaced apart from each other.

Adjacent lens structures among the plurality of lens structures Lb1 to Lbn can overlap each other, be in contact with each other, be spaced apart from each other, or can be provided at different heights. In this case, the different heights can be defined as the shortest distance from the bottom surface 900b of the light guide member 900 to the lowermost end of the lens structures adjacent to each other. As described above, the manner in which two adjacent lens structures among the plurality of lens structures Lb1 to Lbn are provided differently can be defined as the plurality of lens structures Lb1 to Lbn being irregularly arranged. According to an embodiment of the present disclosure, since the plurality of lens structures Lb1 to Lbn are irregularly arranged, occurrence of mura patterns, for example, rainbow mura or ring mura can be prevented.

When two adjacent lens structures among the plurality of lens structures Lb1 to Lbn overlap each other, two adjacent lens structures among the plurality of lens structures Lb1 to Lbn can include a lens overlapping part LOb, which is an area formed to overlap each other. For example, the first lens structure Lb1 and the second lens structure Lb2 are formed to overlap each other, so that a lens overlapping part LOb can be formed between the first lens structure Lb1 and the second lens structure Lb2. For example, the second lens structure Lb2 and the third lens structure Lb3 are formed to overlap each other, so that a lens overlapping part LOb can be formed between the second lens structure Lb2 and the third lens structure Lb3. For example, the third lens structure Lb3 and the fourth lens structure Lb4 are formed to overlap each other, so that a lens overlapping part LOb can be formed between the third lens structure Lb3 and the fourth lens structure Lb4. However, the present disclosure is not limited thereto.

Meanwhile, any one of the plurality of lens structures Lb1 to Lbn can serve to connect two adjacent lens structures to each other. According to an embodiment of the present disclosure, the lens structure of any one of the continuously provided lens structures can perform the same function as the lens connection part provided in the light guide part 400 according to an embodiment of the present disclosure. Accordingly, any one of the lens structures Lb1 to Lbn functioning as a lens connection part can connect two adjacent lens structures to reduce a height difference between the lowest points of the lens structures of different sizes provided continuously and the concave portions provided therebetween, thereby suppressing or removing the occurrence of a sparkle.

For example, the second lens structure Lb2 can be provided on one side, for example, the right side of the first lens structure Lb1, and the second lens structure Lb2 and the first lens structure Lb1 can be provided continuously while sharing the lens overlapping part LOb. the second lens structure Lb2 can be provided on one side, for example, the left side of the third lens structure Lb3, and the second lens structure Lb2 and the third lens structure Lb3 can be provided continuously while sharing the lens overlapping part LOb. In this case, the second lens structure Lb2 can be a lens connection part connecting the first lens structure Lb1 and the third lens structure Lb3. for example, the third lens structure Lb3 can be provided on one side, for example, the right side of the second lens structure Lb2, and the third lens structure Lb3 and the second lens structure Lb2 can be provided continuously while sharing the lens overlapping part LOb. the third lens structure Lb3 can be provided on one side, for example, the left side of the fourth lens structure Lb4, and the third lens structure Lb3 and the fourth lens structure Lb4 can be provided continuously while sharing the lens overlapping part LOb. In this case, the third lens structure Lb3 can be a lens connection part connecting the second lens structure Lb2 and the fourth lens structure Lb4.

According to an embodiment of the present disclosure, since the first lens structure Lb1 and the second lens structure Lb2 are formed to overlap each other, a concave second point P2′ from the bottom surface 900b of the light guide member 900 can be formed between the peak of each of the first lens structure Lb1 and the second lens structure Lb2 in a region of the first convex surface 913a in which the lens overlapping part LOb is formed. In this case, a second height difference ΔH2′ can be formed in the vertical direction between any one of the peak points of each of the first lens structure Lb1 and the second lens structure Lb2 and the second point P2′. According to an embodiment of the present disclosure, since the second height difference ΔH2′ is relatively smaller than that of the case where there is no lens overlapping part Lb due to the lens overlapping part LOb, the height between the peak point of each of the first lens structure Lb1 and the second lens structure Lb2 that are provided continuously and the second point P2′ is relatively reduced, and thus, generation of a sparkle can be suppressed or removed.

According to another embodiment of the present disclosure, at least two lens structures among the plurality of lens structures Lb1 to Lbn can have different sizes. In this case, since the plurality of lens structures Lb1 to Lbn have different sizes, and two adjacent lens structures among the plurality of lens structures Lb1 to Lbn share the lens overlapping part LOb and are continuously provided, the first convex surface 913a of the pattern part 913 can be irregularly formed at different heights. Furthermore, the top surfaces of the plurality of lens patterns 910 can be irregularly formed at different heights. Accordingly, since the top surfaces of the plurality of lens patterns 910 are irregularly formed, occurrence of mura patterns, for example, rainbow mura or ring mura can be prevented.

Any one of the plurality of lens structures Lb1 to Lbn can have a second short axis length B1′ in the vertical direction and a second long axis length B2′ in the horizontal direction. In this case, the vertical direction can be a direction in which the top surface 900a and the bottom surface 900b of the light guide member 900 face each other, and the horizontal direction can be a direction perpendicular to the vertical direction. In this case, the second long axis length B2′ can be provided to be greater than the second short axis length B1′. Furthermore, the second short axis length B1′ can mean the shortest distance between a peak and a lowermost point of any one of the plurality of lens structures Lb1 to Lbn, and the second long axis length B2′ can mean the shortest distance between a left end and a right end of any one of the plurality of lens structures Lb1 to Lbn.

According to an embodiment of the present disclosure, at least one lens structure among the plurality of lens structures Lb1 to Lbn can have an elliptical shape having the second short axis length B1′ and the second long axis length B2′. For example, the first lens structure Lb1 and the second lens structure Lb2 can have elliptical shapes having different sizes, and can partially overlap each other. In this case, each of the second short axis length B1′ and the second long axis length B2′ of the first lens structure Lb1 can be greater than each of the second short axis length B1′ and the second long axis length B2′ of the second lens structure Lb2.

The filling layer 930 can be provided on the plurality of lens patterns 910 and can form a top surface 900a of the light guide member 900. The filling layer 930 can be configured to surround the top surface of the plurality of lens patterns 910. In detail, the filling layer 930 can include a material having a second refractive index. In this case, the second refractive index of the filling layer 930 can be greater than the first refractive index of the plurality of lens patterns 910. For example, a difference between the second refractive index and the first refractive index can be 0.05 or more and 0.10 or less.

When the difference between the first refractive index and the second refractive index is less than 0.05, Sparkle can be visually recognized and distortion can occur in the image, and when the difference between the first refractive index and the second refractive index exceeds 0.10, material reliability between the plurality of lens patterns 910 and the filling layer 930 can be reduced, making it difficult to easily manufacture the light guide member 900.

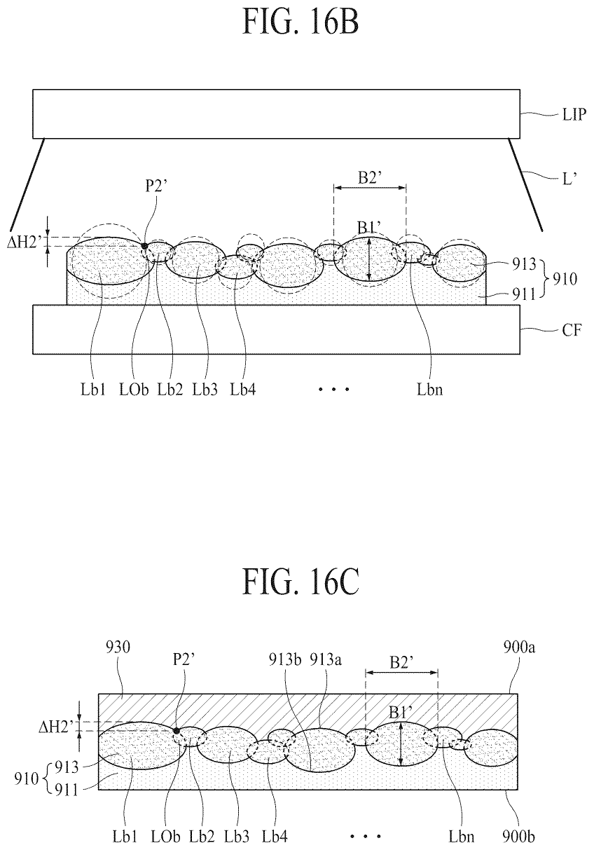

FIGS. 16A to 16C are cross-sectional views schematically illustrating a process of manufacturing a light guide member according to another embodiment. Particularly, the cross-sectional views of FIGS. 16A to 16C relate to an embodiment of FIG. 15, and the same reference numerals are assigned to the same configuration, and repeated descriptions are omitted or may be briefly provided.

First, as shown in FIG. 16A, a resin composition 915 can be applied onto the carrier film CF. Specifically, the resin composition 915 can be applied on one surface, for example, the top surface of the carrier film CF.

The resin composition 915 can be a flowable material having a viscosity equal to or higher than a predetermined level. Therefore, even when the resin composition 915 is applied to one surface of the carrier film CF, the resin composition 915 can not deviate from the carrier film CF.

The resin composition 915 includes a curable material 915a and a sintering material 915b. Specifically, the sintering material 915b is dispersed in or on the surface of the curable material 915a. Since the resin composition 915 includes the curable material 915a and the sintering material 915b dispersed in or on the surface of the curable material 915a, the sintering material 915b dispersed in the resin composition 915 can be irregularly disposed when the resin composition 915 is applied to the carrier film CF.

In the resin composition 915, a ratio of the sintering material 915b to the curable material 915a can be greater than or equal to 2 wt % and less than or equal to 3 wt %. When the ratio of the sintering material 915b to the curable material 915a is less than 2 wt %, the ratio of the sintering material 915b in the resin composition 915 is reduced, and thus a mura improvement effect or a sparkle improvement effect can be reduced, and when the ratio of the sintering material 915b to the curable material 915a exceeds 3 wt %, the sintering material 915b can overlap each other to aggregate particles, thereby reducing a mura improvement effect or a sparkle improvement effect.

The curable material 915a can include a photo-curable material. However, the present disclosure is not limited thereto. The curable material 915a can include a material that is cured by light in a visible light wavelength band region or an ultraviolet wavelength band region, for example. Specifically, the curable material 915a can be cured by light having a wavelength of, for example, 200 nm or more and 1000 nm or less. The curable material 915a can be, for example, an acrylic resin, but is not limited thereto. The curable material 915a can be cured by, for example, a xenon lamp.

The sintering material 915b can be dispersed in the curable material 915a. In detail, a portion of the sintering material 915b can be covered by the curable material 915a, another portion of the sintering material 915b is partially covered by the curable material 915a, and the remaining portion can be exposed to the outside. The sintering material 915b can be sintered by light irradiation, but is not limited thereto.

According to an embodiment of the present disclosure, the sintering material 915b can include a plurality of particles of different sizes (i.e., diameters). The sintering material 915b can include a plurality of spherical particles having different sizes, but is not limited thereto, and the sintering material 915b can be a plurality of elliptical particles having different sizes.

When the sintering material 915b is a spherical particle, the sintering material 915b can include a plurality of spherical particles having different sizes in a range of greater than 0 and less than or equal to 90 μm. The sintering material 915b can include a plurality of spherical particles having different sizes among spherical particles having a diameter of greater than 0 and less than or equal to 90 μm. For example, the sintering material 915b can include a plurality of spherical particles having different sizes among spherical particles having a diameter of greater than 0 and less than or equal to 40 μm. For example, the sintering material 915b can include a plurality of spherical particles having different sizes among spherical particles having a diameter equal to or greater than 35 μm and equal to or less than 75 μm. For example, the sintering material 915b can include a plurality of spherical particles having different sizes among spherical particles having a diameter equal to or greater than 70 μm and equal to or less than 90 μm, but is not limited thereto.

The present disclosure is not limited thereto, and when the sintering material 915b is an elliptical particle, the sintering material 915b can include a plurality of elliptical particles having different long axis diameters in a range greater than 0 and less than or equal to 90 μm.

The sintering material 915b can be sintered by light in a visible light wavelength band region or an ultraviolet wavelength band region, for example. Specifically, the sintering material 915b can be sintered by light having a wavelength of, for example, 200 nm or more and 1000 nm or less. The sintering material 915b can be sintered by, for example, a xenon lamp.

The sintering material 915b can include a material sintered by light in the visible light wavelength band region or the ultraviolet wavelength band region. For example, the sintering material 915b can include a metal oxide or silicon oxide (SiO2), but is not limited thereto. When a metal oxide is used as the sintering material 915b, the sintering material 915b can include, for example, at least one of zinc oxide (ZnO), aluminum oxide (Al2O3), magnesium oxide (MgO) and tin oxide (SnO2).

Next, as shown in FIG. 16B, light L′ of a predetermined wavelength band can be irradiated onto the resin composition 915 by using a light irradiation part LIP. In this case, the resin composition 915 can be cured to form a plurality of lens patterns 910.

The light L′ irradiated to the resin composition 915 can be light of a wavelength band for transforming the curable material 915a and the sintering material 915b included in the resin composition 915.

The light L′ can be, for example, light in an ultraviolet wavelength band and a visible light wavelength band. Specifically, the light L′ can be, for example, light having a wavelength equal to or greater than 200 nm and equal to or less than 1000 nm. The light L′ can be, for example, light generated from a xenon Xe lamp.

According to another embodiment of the present disclosure, when the light L′ generated by the light irradiation part LIP is irradiated to the resin composition 915, the curable material 915a in the resin composition 915 can be cured by the light L′, and the sintering material 915b can be sintered from each other by the light L′. In this case, in a case in which the sintering material 915b is a spherical particle, the sintering material 915b can have a length in the vertical direction and a length in the horizontal direction, respectively. Specifically, the sintering material 915b can overlap adjacent sintering materials 915b while being sintered, and the length of the sintering material 915b in the vertical direction can be shorter than the length in the horizontal direction. However, the present disclosure is not limited thereto.

According to another embodiment of the present disclosure, since the sintering material 915b includes a plurality of spherical particles of different sizes, the plurality of spherical particles can be irregularly sintered while the sintering material 915b is irradiated with the light L′. Therefore, the upper surface 913b of the pattern part 913 formed after the sintering of the sintering material 915b can have an irregular shape. By forming in this way, the light guide member 900 according to an embodiment of the present disclosure can prevent the occurrence of mura patterns, for example, ring mura or rainbow mura, and a height difference between adjacent lens structures among the plurality of lens structures Lb1 to Lbn can be reduced to prevent sparkle.

As the curable material 915a is cured and the sintering material 915b is sintered, the curable material 915a can become the base part 911, and the sintering material 915b can become the pattern part 913. Thus, the resin composition 915 can become a plurality of lens patterns 910 according to another embodiment of the present disclosure by the light L′ irradiated from the light irradiation part LIP.

Finally, as shown in FIG. 16C, when the filling layer 930 is applied on the plurality of lens patterns 910 and the carrier film CF provided under the plurality of lens patterns 910 is removed, the light guide member 900 according to another embodiment of the present disclosure can be realized. When the light guide member 900 is manufactured according to another embodiment of the present disclosure, since the plurality of lens patterns 910 are formed using the resin composition 915 in which the curable material 915a and the sintering material 915b are mixed, the manufacturing time of the light guide member 900 can be shortened.

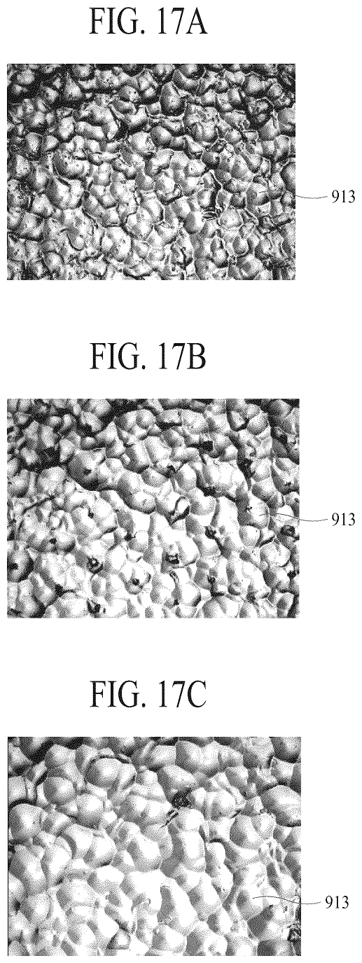

FIGS. 17A to 17C are examples of planar TEM photographs of a light guide member 900 according to another embodiment of the present disclosure. In this case, FIGS. 17A to 17C relate to a case in which the light irradiation part (see LIP in FIG. 16B) irradiates light (see L′ in FIG. 16B) having an intensity of 500 mJ/cm2 with a plurality of spherical particles of different sizes in the range greater than 0 μm and equal to or less than 40 μm, the range equal to or greater than 35 μm and equal to or less than 75 μm, and the range equal to or greater than 70 μm and equal to or less than 90 μm, respectively.

As can be seen from the embodiments of FIGS. 17A to 17C, the roughness Ra of the pattern part 913 can be different depending on the size range of the sintering material (see 915b in FIG. 16A). Specifically, as the size of the sintering material (see 915b in FIG. 16A) is relatively increased, the roughness Ra of the pattern part 913 can be reduced to 0.827 μm, 0.789 μm, and 0.711 μm, respectively.

Accordingly, the present disclosure can have the following advantages.

According to an embodiment of the present disclosure, a plurality of lens patterns and a lens connection part provided in the light guide part are arranged in an atypical state, so that the occurrence of a moire phenomenon and a sparkle phenomenon due to interference between the plurality of lens patterns and the lens connection parts and pixels can be minimized or reduced, so that image quality can be improved and the viewer's visibility of an image can be improved.

According to an embodiment of the present disclosure, the light guide part includes a plurality of lens patterns and a lens connection part having a relatively low refractive index, and a filling layer having a relatively high refractive index, so that a problem that Mura, for example Rainbow Mura and Ring Mura phenomenon caused by external light reflecting on electrodes and wiring inside the display apparatus is recognized can be minimized.

According to an embodiment of the present disclosure, by providing a lens connection part between a plurality of lens patterns, a height difference between each of the plurality of lens patterns and a concave portion between the plurality of lens patterns can be reduced, thereby minimizing the problem of Sparkle being visually recognized.

It will be apparent to those skilled in the art that various substitutions, modifications, and variations are possible within the scope of the present disclosure without departing from the spirit and scope of the present disclosure. Therefore, the scope of the present disclosure is represented by the following claims, and all changes or modifications derived from the meaning, range and equivalent concept of the claims should be interpreted as being included in the scope of the present disclosure.

What is claimed is:

1. An organic light emitting display apparatus comprising:
a display panel including a circuit element layer and a light guide part disposed on the circuit element layer, the light guide part having a bottom surface and a top surface opposite to the bottom surface,
wherein the light guide part includes:
a plurality of lens patterns extending from the bottom surface toward the top surface and disposed irregularly in the light guide part;
a lens connection part disposed between the plurality of lens patterns and in contact with the plurality of lens patterns; and
a filling layer disposed on the plurality of lens patterns and the lens connection part.

2. The organic light emitting display apparatus according to claim 1,
wherein the lens connection part extends along a boundary disposed between the plurality of lens patterns.

3. The organic light emitting display apparatus according to claim 1,
wherein the lens connection part is continuous without being disconnected along a boundary disposed between the plurality of lens patterns.

4. The organic light emitting display apparatus according to claim 1,
wherein two adjacent lens patterns among the plurality of lens patterns are in contact with each other at one point,
and the lens connection part overlaps the one point.

5. The organic light emitting display apparatus according to claim 1,
wherein a bottom surface of the lens connection part and a bottom surface of the plurality of lens patterns constitute the bottom surface of the light guide part.

6. The organic light emitting display apparatus according to claim 1,
wherein the lens connection part includes a plurality of convex structures disposed irregularly.

7. The organic light emitting display apparatus according to claim 6,
wherein at least some of the plurality of convex structures overlap each other.

8. The organic light emitting display apparatus according to claim 6,
wherein the plurality of convex structures and the plurality of lens patterns are provided in a circular shape on a plane, respectively, and a diameter of each of the plurality of convex structures is smaller than a diameter of each of the plurality of lens patterns.

9. The organic light emitting display apparatus according to claim 6,
wherein a radius of curvature of any one of the plurality of convex structures is equal to 10 μm or more and equal to 90 μm or less.

10. The organic light emitting display apparatus according to claim 1,
wherein the plurality of lens patterns includes a first lens pattern having a first height and a second lens pattern having a second height which is different from the first height.

11. The organic light emitting display apparatus according to claim 10,
wherein a part of the lens connection part is disposed between the first lens pattern and the second lens pattern and has a third height, and
the third height is smaller than the first height and the second height.

12. The organic light emitting display apparatus according to claim 10,
wherein the lens connection part includes a first convex structure adjacent to the first lens pattern and a second convex structure adjacent to the second lens pattern, and
the first convex structure and the second convex structure share a partial area with each other.

13. The organic light emitting display apparatus according to claim 10,
wherein the lens connection part includes a plurality of convex structures, and a radius of curvature of each of the first lens pattern and the second lens pattern is smaller than a radius of curvature of each of the plurality of convex structures of the lens connection part.

14. The organic light emitting display apparatus according to claim 1,
wherein a first refractive index of the plurality of lens patterns is smaller than a second refractive index of the filling layer, and
a difference between the first refractive index and the second refractive index equal to or greater than 0.05 and equal to or less than 0.10.

15. The organic light emitting display apparatus according to claim 1,
wherein the plurality of lens patterns are provided in a circular shape on a plane, and any one of the plurality of lens patterns has a diameter of 10 μm or more and 60 μm or less, and
any one of the plurality of lens patterns has a height-diameter ratio of 20% or more and 50% or less.

16. The organic light emitting display apparatus according to claim 14, wherein the lens connection part has the first refractive index.

17. The organic light emitting display apparatus according to claim 1, wherein the light guide part has a haze value equal to or greater than 5% and equal to or less than 15%, preferably, greater than or equal to 7% and less than or equal to 13%.

18. The organic light emitting display apparatus according to claim 1, wherein the lens connection part comprising a plurality of convex structure which form a plurality of concave portions with the plurality of the lens patterns, and the sum of the height of each of the plurality of lens patterns and the height of each of the plurality of concave portions is equal to 0.5 μm or more and equal to 15 μm or less, preferably, equal to 0.8 μm or more and equal to 13 μm or less.

19. A method of manufacturing a light guiding part of an organic light emitting display apparatus, the method comprising:
forming a first pattern using a laser in a surface of a mold, the first pattern comprising a plurality of first concave portions;
forming a second pattern on the surface of the mold by forming a plurality of second concave portions at a boundary located between the plurality of first concave portions of the first patterns through a blasting process;
forming a plurality of lens patterns and a lens connection part between the plurality of lens patterns using the mold including the first pattern and the second pattern; and
forming a filling layer on the plurality of lens patterns and the lens connection part,
wherein the plurality of first concave portions correspond to the plurality of lens patterns, and
the plurality of second concave portions correspond to the lens connection part.

20. The method of manufacturing the light guiding part according to claim 19, wherein the blasting process uses a plurality of beads, and
a size of each of the plurality of beads is equal to or greater than 10 μm and equal to or less than 90 μm.

21. The method of manufacturing the light guiding part according to claim 20,
wherein each bead includes one material among SiO2, Al2O3, Na2O, MgO, CaO, K2O, and TiO2.

22. The method of manufacturing the light guiding part according to claim 19,
wherein the forming the first pattern using the laser in the surface of the mold comprises:
irradiating the laser on the surface of the mold to form a predetermined pattern; and
etching the predetermined pattern using an etchant to form the first pattern, the predetermined pattern having a size smaller than a size of the first pattern.

23. A display device comprising:
a display panel including a circuit element layer and a light guide member disposed on the circuit element layer; and
a light guide member disposed on the display panel, the light guide member including a plurality of lens patterns and a filling layer disposed on the plurality of lens patterns,
wherein each of the plurality of lens patterns include:
a base part; and
a pattern part disposed on the base part, and
wherein the pattern part includes:
a first lens structure and a second lens structure having a same shape, wherein the first lens structure and the second lens structure overlap each other to form a lens overlapping part.

24. The display device according to claim 23,
wherein the plurality of lens patterns are irregularly arranged.

25. The display device according to claim 23,
wherein the pattern part and the base part include different materials.

26. The display device according to claim 25,
wherein the base part includes an acryl-based material.

27. The display device according to claim 25,
wherein the pattern part includes one of zinc oxide, aluminum oxide, magnesium oxide, tin oxide, and silicon oxide.

28. The display device according to claim 23,
wherein a refractive index of the pattern part and a refractive index of the base part are same.

29. The display device according to claim 23,
wherein the first lens structure and the second lens structure are disposed to have a same size.

30. The display device according to claim 23,
wherein the plurality of lens patterns are formed by irradiating light to a resin composition containing a curable material and a sintering material disposed in the curable material, and the sintering material contains a plurality of spherical or elliptical particles of a same size.

31. The display device according to claim 23,
wherein the first lens structure and the second lens structure are disposed in different sizes.

32. The display device according to claim 23,
wherein the plurality of lens patterns are formed by irradiating light to a resin composition containing a curable material and a sintering material disposed in the curable material, and the sintering material contains a plurality of spherical or elliptical particles of different sizes.

33. The display device according to claim 28, wherein the filling layer has a refractive index greater than the refractive index of the pattern part.

34. The display device according to claim 30, wherein the sintering material is partially covered by the curable material.

35. The display device according to claim 34, wherein a ratio of the sintering material to the curable material is greater than or equal to 2 wt % and less than or equal to 3 wt %.

36. The display device according to claim 34, wherein when the sintering material is a spherical particle, the spherical particle has a diameter in a range of greater than 0 and less than or equal to 90 μm, and when the sintering material is an elliptical particle, the elliptical particle has a long axis diameter in a range greater than 0 and less than or equal to 90 μm.
